(19) United States
(12) Patent Application Publication
(10) Pub. No.: US 2025/0324596 A1
(43) Pub. Date: Oct. 16, 2025

(54) SEMICONDUCTOR DEVICE AND AN ELECTRONIC SYSTEM INCLUDING THE SEMICONDUCTOR DEVICE

(71) Applicant: Samsung Electronics Co., Ltd., Suwon-si (KR)

(72) Inventors: Kohji KANAMORI, Suwon-si (KR); Seo-Goo KANG, Suwon-si (KR); Sanghun CHUN, Suwon-si (KR); Jeehoon HAN, Suwon-si (KR)

(73) Assignee: Samsung Electronics Co., Ltd., Suwon-si (KR)

(21) Appl. No.: 18/882,084

(22) Filed: Sep. 11, 2024

(30) Foreign Application Priority Data
Apr. 11, 2024 (KR) 10-2024-0048931

(51) Int. Cl. H10B 43/27; H10B 41/27; H10B 41/35; H10B 43/35

(52) U.S. Cl. CPC H10B 43/27; H10B 41/27; H10B 41/35; H10B 43/35

(57) ABSTRACT

A semiconductor device including a gate stacking structure having stacked interlayer insulation layers and gate electrodes; a separation structure penetrating the gate stacking structure; a separation pattern separating some of the gate electrodes; a channel structure penetrating the gate stacking structure; a channel insulation layer on the gate stacking structure and including grooves; a bit line contact in a groove and connected with the channel structure; a bit line insulation layer on the bit line contact; and a bit line on the bit line insulation layer and connected with the bit line contact. A planar area of the bit line contact is larger than that of the channel structure in contact with the bit line contact. Planar shapes of portions of the bit line contact contacting the separation pattern and not contacting the separation pattern are different. The separation pattern and bit line insulation layer are connected through the groove.

### CROSS-REFERENCE TO RELATED APPLICATION

This application claims priority to and the benefit of Korean Patent Application No. 10-2024-0048931 filed in the Korean Intellectual Property Office on Apr. 11, 2024, the entire contents of which are incorporated herein by reference.

### BACKGROUND

The present disclosure relates to semiconductor devices and electronic systems including the semiconductor device.

In electronic systems that require data storage, semiconductor devices that can store high-capacity data are required. Accordingly, methods to increase data storage capacity of semiconductor devices are being researched. For example, as one of the methods to increase data storage capacity of semiconductor devices, a semiconductor device containing memory cells arranged three-dimensionally instead of two-dimensionally arranged memory cells has been suggested.

### SUMMARY

Some example embodiments provide a semiconductor device that can reduce misalignment during a manufacturing process and improve reliability, and an electronic system including the same.

Some example embodiments provided a semiconductor device that includes a gate stacking structure including a plurality of interlayer insulation layers and a plurality of gate electrodes that are alternately stacked; a separation structure penetrating the gate stacking structure; a separation pattern separating some of the plurality of gate electrodes at a bottom side of the gate stacking structure; a channel structure penetrating the gate stacking structure; a channel insulation layer on the gate stacking structure, the channel insulation layer defining a plurality of grooves therein; a bit line contact in a groove from among the plurality of grooves, the bit line contact being electrically connected with the channel structure and being in contact with the separation pattern; a bit line insulation layer on the bit line contact; and a bit line on the bit line insulation layer, the bit line being electrically connected with the bit line contact. A planar area of the bit line contact is larger than a planar area of the channel structure that is in contact with the bit line contact. A planar shape of a portion of the bit line contact in contact with the separation pattern is different than a planar shape of another portion of the bit line contact that is not in contact with the separation pattern. The separation pattern and the bit line insulation layer are integrally connected through the groove penetrating the channel insulation layer.

Some example embodiments further provide a semiconductor device that includes a gate stacking structure including a plurality of interlayer insulation layers and a plurality of gate electrodes that are alternately stacked; a separation structure penetrating the gate stacking structure along a first direction, the separation structure extending in a second direction; a separation pattern separating some of the plurality of gate electrodes at a bottom side of the gate stacking structure, the separation pattern penetrating the gate stacking structure along the first direction and extending in the second direction; a channel structure between the separation structure and the separation pattern on a plane, the channel structure penetrating the gate stacking structure along the first direction; a channel insulation layer on the gate stacking structure, the channel insulation layer defining a plurality of grooves therein; a bit line contact in a groove from among the plurality of grooves, the bit line contact being electrically connected with the channel structure and being in contact with the separation pattern; a bit line insulation layer on the bit line contact; a bit line on the bit line insulation layer, the bit line extending in a third direction that is perpendicular to the second direction, and the bit line being electrically connected with the bit line contact; and a contact via between the bit line contact and the bit line. The separation pattern and the bit line insulation layer are integrally connected through the groove penetrating the channel insulation layer. A planar area of the bit line contact is larger than a planar area of the channel structure that is in contact with the bit line contact. A planar shape of the bit line contact has a circular shape in some regions and has a non-circular shape in other regions.

Some example embodiments still further provide an electronic system that includes a main substrate; a semiconductor device on the main substrate; and a controller electrically connected with the semiconductor device on the main substrate. The semiconductor device includes a gate stacking structure including a plurality of interlayer insulation layers and a plurality of gate electrodes that are alternately stacked; a separation structure penetrating the gate stacking structure; a separation pattern separating some of the plurality of gate electrodes at a bottom side of the gate stacking structure; a channel structure penetrating the gate stacking structure; a channel insulation layer on the gate stacking structure, the channel insulation layer defining a plurality of grooves therein; a bit line contact in a groove from among the plurality of grooves, the bit line contact being electrically connected with the channel structure and being in contact with the separation pattern; a bit line insulation layer on the bit line contact; and a bit line on the bit line insulation layer, the bit line being electrically connected with the bit line contact. A planar area of the bit line contact is larger than a planar area of the channel structure that is in contact with the bit line contact. A planar shape of a portion of the bit line contact in contact with the separation pattern is different than a planar shape of another portion of the bit line contact that is not in contact with the separation pattern. The separation pattern and the bit line insulation layer are integrally connected through the groove penetrating the channel insulation layer.

According to the some example embodiments, it is possible to provide a semiconductor device that reduces misalignment during the manufacturing process and improves reliability, and an electronic system including the same.

### BRIEF DESCRIPTION OF THE DRAWINGS

FIG. 1 is a schematic top plan view of a semiconductor device according to some example embodiments.

FIG. 2 is a cross-sectional view of FIG. 1, taken along the line A-A′.

FIG. 3 is an enlarged cross-sectional view of the region A in FIG. 2 according to some example embodiments.

FIG. 4 shows a cross-sectional view of FIG. 1, taken along line A-A′ according to some example embodiments.

FIG. 5 is a schematic top plan view of a semiconductor device according to some example embodiments.

FIG. 6 is a cross-sectional view of FIG. 5, taken along the line B-B′ according to some example embodiments.

FIG. 7 is a cross-sectional view as FIG. 5, taken along the line B-B′ according to some example embodiments.

FIGS. 8, 9, 10, 11, 12, 13, 14, 15, 16, 17, 18, 19, 20, 21, 22, 23, 24 and 25 show a manufacturing process according to some example embodiments.

FIG. 26 schematically shows an electronic system including a semiconductor device according to some example embodiments.

FIG. 27 is a perspective view that schematically shows an electronic system including the semiconductor device according to some example embodiments.

FIG. 28 conceptually shows a region cut from the semiconductor package 2003 of FIG. 27, taken along the line II-II′.

### DETAILED DESCRIPTION

The inventive concepts will be described more fully hereinafter with reference to the accompanying drawings, in which some example embodiments of the inventive concepts are shown. As those skilled in the art would realize, the described some example embodiments may be modified in various different ways, all without departing from the spirit or scope of the present inventive concepts.

In the drawings, the thickness of layers, films, panels, regions, etc., are exaggerated for clarity. Like reference numerals designate like elements throughout the specification. It will be understood that when an element such as a layer, film, region, or substrate is referred to as being “on” another element, it can be directly on the other element or intervening elements may also be present. In contrast, when an element is referred to as being “directly on” another element, there are no intervening elements present.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

Also, for example, “at least one of A, B, and C” and similar language (e.g., “at least one selected from the group consisting of A, B, and C”) may be construed as A only, B only, C only, or any combination of two or more of A, B, and C, such as, for instance, ABC, AB, BC, and AC.

A semiconductor device and an electronic system according to some example embodiments will be described in detail with reference to the drawings.

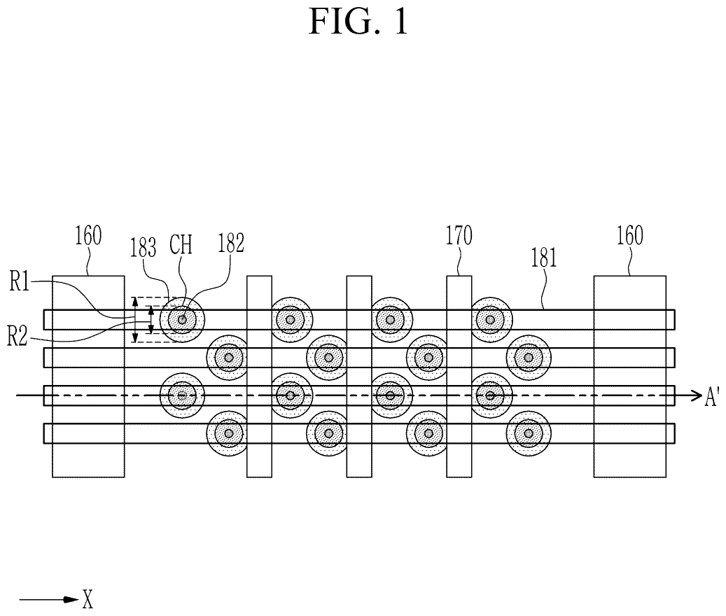

Hereinafter, a semiconductor device according to some example embodiments will be described with reference to FIG. 1 to FIG. 5.

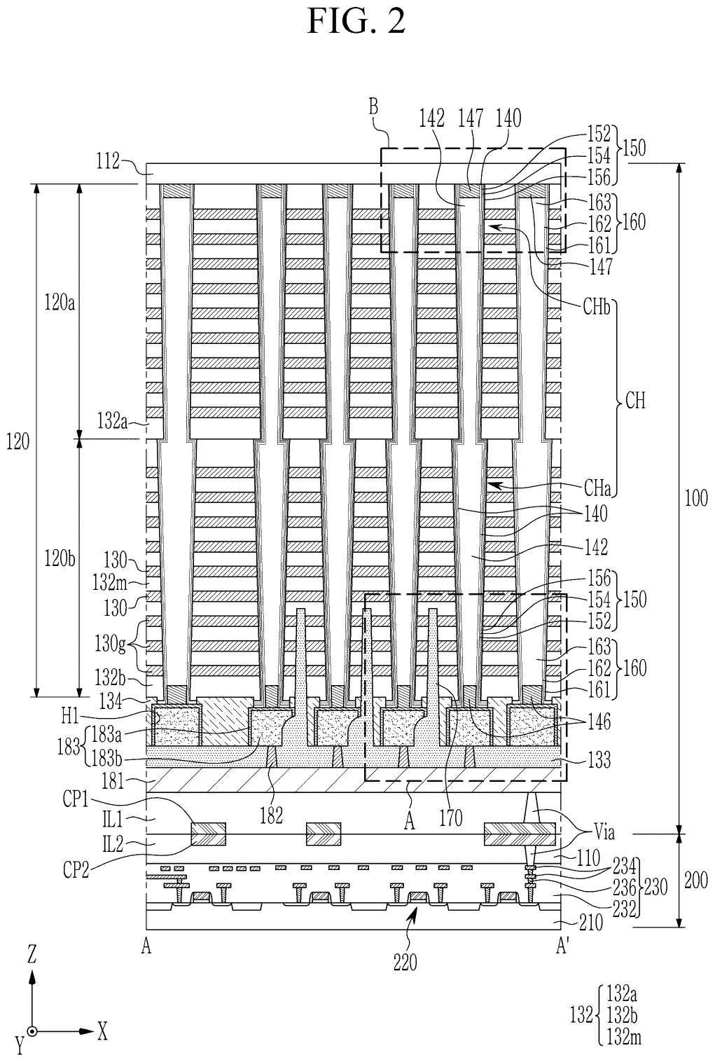

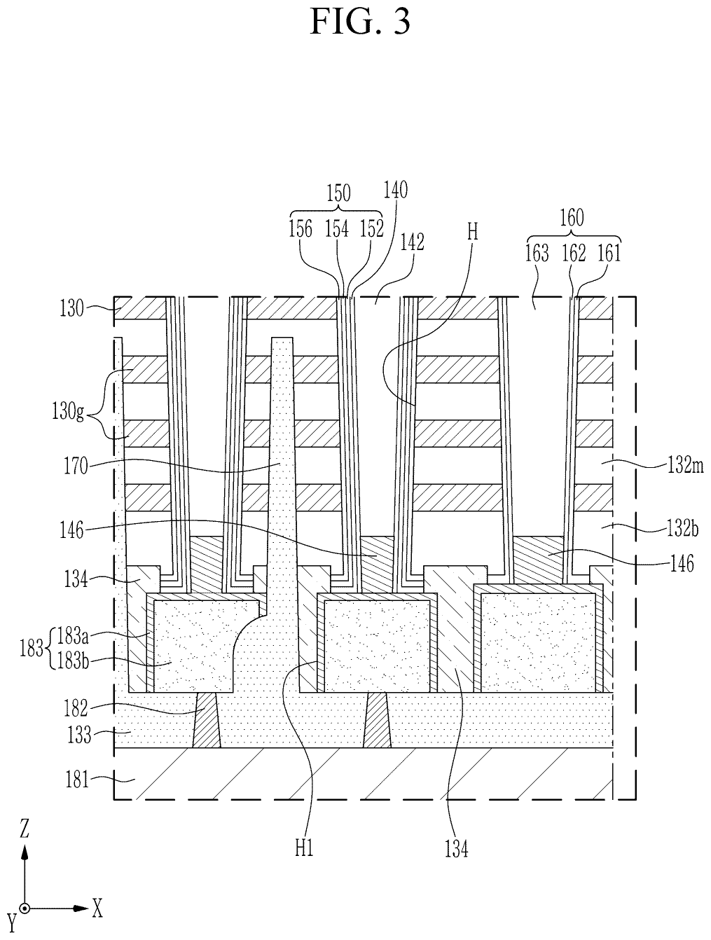

FIG. 1 is a schematic top plan view of a semiconductor device according to some example embodiments. FIG. 2 is a cross-sectional view of FIG. 1, taken along the line A-A′. FIG. 3 is an enlarged cross-sectional view of the region A in FIG. 2.

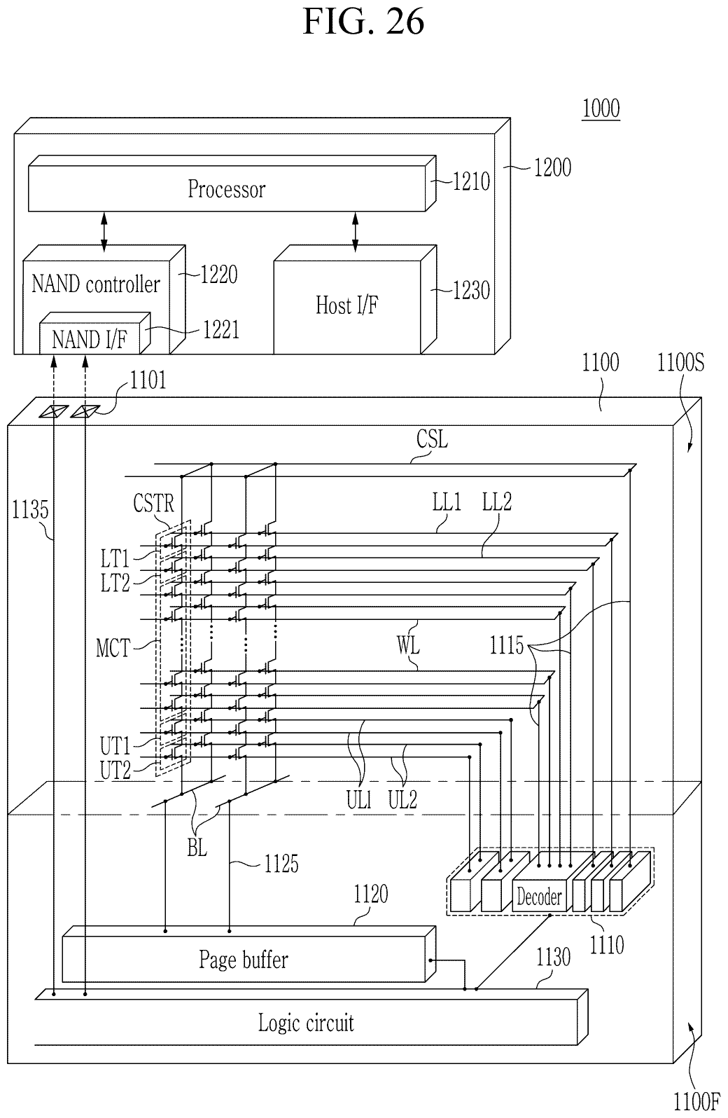

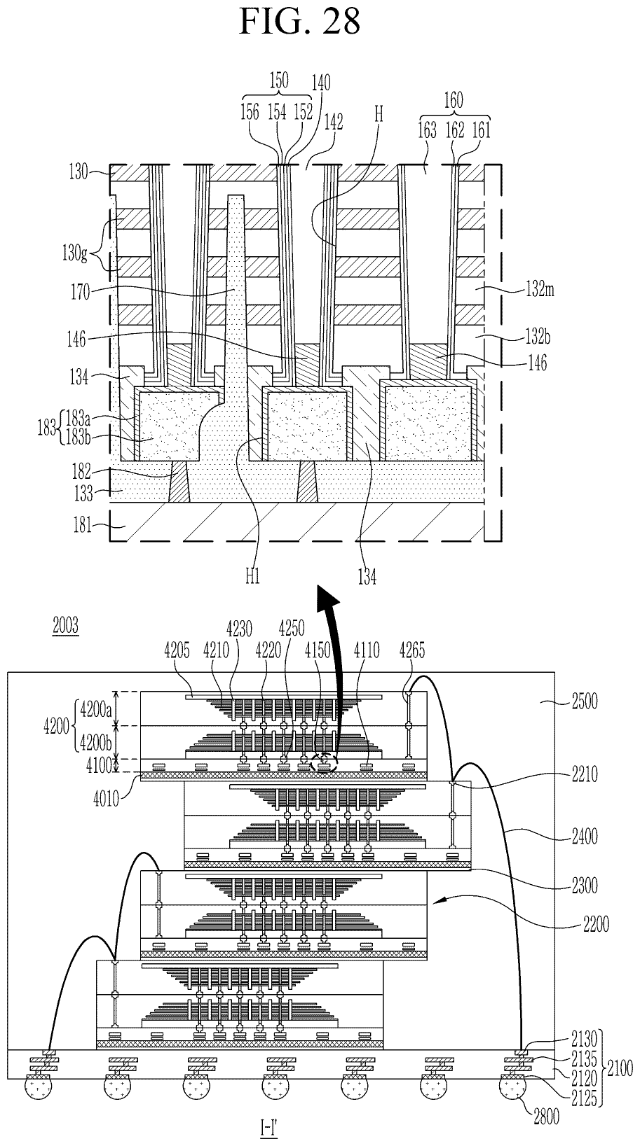

Referring to FIG. 1 to FIG. 3, a semiconductor device according to some example embodiments may include a cell region 100 provided with a memory cell structure and a circuit region 200 provided with a peripheral circuit structure that controls the operation of the memory cell structure. For example, the circuit region 200 and the cell region 100 may be portions respectively corresponding to a first structure 1100F and a second structure 1100S of a semiconductor device 1100 included in an electronic system 1000 shown in FIG. 26. Alternatively, the circuit region 200 and the cell region 100 may be respectively portions including a first structure 4100 and a second structure 4200 of a semiconductor chip 2200 shown in FIG. 28.

The circuit region 200 may include the peripheral circuit structure formed on the first substrate 210, and the cell region 100 may be provided with a gate stacking structure 120 and a channel structure CH as the memory cell structure. In some example embodiments, the cell region 100 may be disposed on the circuit region 200. According to this, the area corresponding to the circuit region 200 does not need to be secured separately from the cell region 100, and thus the area of the semiconductor device can be reduced. However, some example embodiments is not limited to this, and the circuit region 200 may be positioned next to the cell region 100. Numerous other variations are possible.

The circuit region 200 may include a first substrate 210, and a circuit element 220 and a first wiring portion 230 formed on the first substrate 210.

The first substrate 210 may be a semiconductor substrate containing a semiconductor material. For example, the first substrate 210 may be a semiconductor substrate made of a semiconductor material or may be a semiconductor substrate in which a semiconductor layer is formed on a base substrate. For example, the first substrate 210 may be formed of monocrystalline or polycrystalline silicon, epitaxial silicon, germanium, silicon-germanium, silicon-on-insulator (SOI), germanium-on-insulator (GOI), and the like.

The circuit element 220 formed on the first substrate 210 may include various circuit elements controlling the operation of the memory cell structure provided in the cell region 100. For example, the circuit element 220 may form the peripheral circuit structure such as a decoder circuit (refer to 1110 in FIG. 26), a page buffer (refer to 1120 in FIG. 26), a logic circuit (refer to 1130 in FIG. 26), and the like.

The circuit element 220 may include, for example, a transistor, but is not limited thereto. For example, the circuit element 220 may include active elements such as a transistor and passive elements such as a capacitor, a resistor, and an inductor.

The first wiring portion 230 disposed on the first substrate 210 may be electrically connected with the circuit element 220. In some example embodiments, the first wiring portion 230 may include a plurality of wiring layers 234 disposed at a distance from each other while disposing the wire insulation layer 232 therebetween and connected with each other to form a desired path by a contact via 236. The wiring layer 234 or the contact via 236 may contain various conductive materials, and the wire insulation layer 232 may contain various insulating materials.

The circuit region 200 may include a second insulation layer IL2 disposed on the first wiring portion 230. The second insulation layer IL2 includes a second pad CP2, and the second pad CP2 of the second insulation layer IL2 and the wiring layer 234 may be connected with each other through a via VIA. The second pad CP2 may contain copper, but is not limited thereto.

The cell region 100 includes a gate stacking structure 120 and a channel structure CH. A structure for connecting the gate stacking structure 120 and/or the channel structure CH formed in the cell region 100 to the circuit region 200 or an external circuit may be disposed.

The cell region 100 may include a first insulation layer IL1 disposed in contact with the circuit region 200. The first insulation layer IL1 may include a first pad CP1, and the first pad CP1 of the first insulation layer IL1 and a bit line 181 may be connected with each other through the via VIA. The first pad CP1 may contain copper, but is not limited thereto. As shown in FIG. 2, the first pad CP1 and the second pad CP2 may directly contact each other. That is, the cell region 100 and the circuit region 200 may be connected with each other through the first pad CP1 and the second pad CP2. The first pad CP1 and the second pad CP2 may contain copper, but are not limited thereto.

The gate stacking structure 120 where the cell insulation layers 132 and gate electrodes 130 are alternately stacked and the channel structure CH extending in a third direction (Z-axis direction) through the gate stacking structure 120 may be formed in the cell region 100.

The cell insulation layer 132 may include an interlayer insulation layer 132m that is disposed between two adjacent gate electrodes 130 in each of the plurality of gate stacking structures 120a and 120b and upper insulation layers 132a and 132b disposed in upper portions of each of the plurality of gate stacking structures 120a and 120b. In some example embodiments, the plurality of cell insulation layers 132 may not have uniform thickness. For example, thicknesses of the upper insulation layers 132a and 132b may be greater than a thickness of the interlayer insulation layer 132m.

The gate electrode 130 may contain various conductive materials. The cell insulation layer 132 may include various insulating materials. For example, the gate electrode 130 may contain a metal material (e.g., tungsten (W), copper (Cu), aluminum (Al), molybdenum (Mo), and the like), polycrystalline silicon, a metal nitride (e.g., titanium nitride (TiN), a tantalum nitride (TaN), and the like), or a combination thereof. For example, the cell insulation layer 132 may include silicon oxide, silicon nitride, silicon oxynitride, a low dielectric constant material that has a smaller dielectric constant than silicon oxide, or a combination thereof.

In some example embodiments, the channel structure CH that penetrates through the gate stacking structure 120 and extends in a direction that intersects the first substrate 210 (for example, a vertical direction perpendicular to the first substrate 210) (Z-axis direction of drawing) may be formed.

Simultaneously referring to FIG. 2 and FIG. 3, the channel structure CH may include a channel layer 140 and a gate dielectric layer 150 disposed on the channel layer 140 between the gate electrode 130 and the channel layer 140. The channel structure CH may further include a core insulation layer 142 disposed inside the channel layer 140, but the core insulation layer 142 may not be provided according to another example. The channel structure CH may include a first semiconductor pattern 146 and a second semiconductor pattern 147 disposed on lateral ends of the channel structure CH. The gate dielectric layer 150 disposed between the gate electrode 130 and the channel layer 140 may include a tunneling layer 152, a charge storage layer 154, and a blocking layer 156 that are sequentially stacked on the channel layer 140.

Each channel structure CH forms one memory cell string, and a plurality of channel structures CH may be arranged to be spaced apart from each other on a plane, forming rows and columns. For example, on a plane, the plurality of channel structures CH may be arranged in various shapes, such as a lattice shape or a zigzag shape. The channel structure CH may have a pillar shape. However, some example embodiments are not limited thereto, and the arrangement, structure, and shape of the channel structure CH may be modified in various ways.

The channel layer 140 may include a semiconductor material, for example, monocrystalline silicon or polycrystalline silicon. A core insulation layer 142 may include various insulating materials. For example, the core insulation layer 142 may include silicon oxide, silicon nitride, silicon nitride, or a combination thereof.

The tunneling layer 152 may include an insulating material (e.g., silicon oxide, silicon oxynitride, etc.) capable of tunneling of charges. The charge storage layer 154 is used as a data storage region, and the charge storage layer 154 may include polycrystalline silicon, silicon nitride, and the like. The blocking layer 156 may include an insulating material that can limit and/or prevent undesired charge inflow into the gate electrode 130. For example, the blocking layer 156 may include silicon oxide, silicon nitride, silicon oxynitride, a high dielectric constant material that has a higher dielectric constant than silicon oxide, or a combination thereof.

However, a material, a stacking structure, and the like of the channel layer 140, the core insulation layer 142, and the gate dielectric layer 150 may be modified in various ways, and some example embodiments are not limited thereto.

As shown in FIG. 2, the first semiconductor pattern 146 and the second semiconductor pattern 147 may be arranged to be electrically connected to the channel layer 140 at both ends of the channel structure CH. The first semiconductor pattern 146 and the second semiconductor pattern 147 may be disposed within a region where the core insulation layer 142 has been removed and may contact the channel layer 140. The first semiconductor pattern 146 and the second semiconductor pattern 147 may include epitaxial silicon, epitaxial germanium, polycrystalline silicon, monocrystalline silicon, polycrystalline germanium, or monocrystalline germanium with or without dopant doped therein. For example, the first semiconductor pattern 146 and the second semiconductor pattern 147 may include N+-doped polycrystalline silicon.

In some example embodiments, the gate stacking structure 120 may include a plurality of gate stacking structures 120a and 120b that are sequentially stacked. Then, the number of stacked gate electrodes 130 may be increased, thereby increasing the number of memory cells with a stable structure. In the drawing, it is illustrated that the gate stacking structure 120 includes first and second gate stacking structures 120a and 120b. However, some example embodiments are not limited thereto, and the gate stacking structure 120 may be formed of one gate stacking structure, or may be formed of three or more gate stacking structures.

As described above, when the plurality of gate stacking structures 120a and 120b are provided, the channel structure CH may have a plurality of channel structures Cha and CHb penetrating the plurality of gate stacking structures 120a and 120b, respectively. The plurality of channel structures CHa and CHb may be connected to each other. The plurality of channel structures CHa and CHb each has an inclined side such that a width narrows as it approaches a bit line contact 183 according to the aspect ratio when viewed in cross-section, and a bent portion may be formed due to a width difference at a connection portion of the plurality of channel structures CHa and CHb. As another example, the plurality of channel structures CHa and CHb may have continuous inclined sides without having a bent portion. It is illustrated in FIG. 2 that a gate dielectric layer 150, a channel layer 140, and a core insulation layer 142 of the plurality of channel structures CHa and CHb extend with each other such that an integral structure is formed. However, some example embodiments are not limited thereto, and the gate dielectric layer 150, the channel layer 140, and the core insulation layer 142 of the plurality of channel structures CHa and CHb may be formed separately from each other and electrically connected to each other. A separate channel pad may be provided in a connection portion of the plurality of channel structures CHa and CHb. As such, some example embodiments are not limited to the shape of the plurality of channel structures CHa and CHb.

In some example embodiments, the gate stacking structure 120 may be partitioned into a plurality of structures on a plane by a separation structure 160 that extends in a direction (e.g., a perpendicular direction, Z-axis direction in the drawing) crossing the first substrate 210 and penetrates the gate stacking structure 120. A separation pattern 170 may be formed on one side of the gate stacking structure 120 (e.g., at a bottom of the gate stacking structure 120 along the Z-axis direction shown in FIG. 2). Simultaneously referring to FIG. 1, on the plane, the separation structure 160 and/or separation pattern 170 extends in the second direction (Y-axis direction of drawing) and may be provided as a plurality so as to be separated from each other at a desired (and/or alternatively predetermined) distance in the first direction (X-axis direction of drawing) that intersects the second direction.

On a plane, the plurality of gate stacking structures 120 extend in the second direction (Y-axis direction of drawing), and may be spaced apart from each other at a desired (and/or alternatively predetermined) distance in the first direction (X-axis direction of drawing) by the separation structure 160. The gate stacking structure 120 partitioned by the separation structure 160 may form one memory cell block. However, some example embodiments are not limited thereto, and the range of the memory cell block is not limited thereto.

For example, the separation structure 160 may penetrate the gate stacking structure 120, and the separation pattern 170 may separate one or only a portion of the plurality of gate electrodes 130 from each other.

The separation pattern 170 may be disposed between the separation structures 160. A plurality of separation patterns 170 may be disposed between adjacent separation structures 160. In some example embodiments, the gate electrode 130 separated by the separation pattern 170 may be referred to as a selective gate electrode 130g. In some example embodiments, the selective gate electrode 130g may be a string selection gate electrode that selects a string, and the separation pattern 170 may be a string separation pattern that separates the string. Depending on some example embodiments, the selective gate electrode 130g may further include a gate electrode other than the string selection gate that selects the string.

As an example, the separation structure 160 is illustrated as having an inclined surface of which a width gradually decreases as it approaches a bit line contact 183 when viewed in cross-section due to a high aspect ratio, but some example embodiments are not limited thereto. FIG. 2 shows a configuration in which the separation structure 160 has a bent portion at a connection portion of the plurality of gate stacking structures 120a and 120b, but the separation structure 160 may not be provided with the bent portion at the connection portion of the plurality of gate stacking structures 120a and 120b.

The separation structure 160 or separation pattern 170 may be filled with various insulating materials. For example, the separation structure 160 or separation pattern 170 may include an insulating material such as silicon oxide, silicon nitride, or silicon oxynitride. It is illustrated in FIG. 2 and FIG. 3 that the separation structure 160 is formed with the first layer 161, the second layer 162, the third layer 163, the first semiconductor pattern 146, and the second semiconductor pattern 147, but is not limited thereto. In some example embodiments, the first layer 161 of the separation structure 160 may include silicon oxide, the second layer 162 may include silicon nitride, and the third layer 163 may include silicon oxide, but this is only an example, and the present disclosure is not limited thereto.

As shown in FIG. 2, a channel insulation layer 134, a bit line contact 183, a bit line insulation layer 133, a contact via 182, and a bit line 181 may be disposed between the channel structure CH and the circuit region 200.

As shown in FIG. 2, the separation pattern 170 and the bit line insulation layer 133 may be connected as one through a groove penetrating the channel insulation layer 134. This is a structure derived because the separation pattern 170 is formed through the channel insulation layer 134 during the manufacturing process, and thus a planar area of the separation pattern 170 formed on the channel insulation layer 134 may be larger than a planar area of the separation pattern 170 disposed inside the gate stacking structure 120.

Referring to FIG. 1, the bit line 181 may be extended in the first direction (X-axis direction of drawing) that intersects the second direction in which the gate electrode 130 extends. The bit line 181 may be electrically connected with the channel structure CH through the contact via 182 and the bit line contact 183. Hereinafter, a connection of the channel structure CH and the bit line 181 will be described.

Referring to FIG. 2 and FIG. 3, a channel insulation layer 134 may be disposed at one side of the channel structure CH (e.g., below the gate stacking structure 120 along the Z-axis direction). The channel insulation layer 134 may include silicon oxide, silicon nitride, silicon oxynitride, a low dielectric constant material, and the like. For example, the channel insulation layer 134 may include SiN or SiON, but is not limited thereto. The channel insulation layer 134 may include (e.g., define therein) a plurality of grooves H1, and the bit line contact 183 may be disposed inside the groove H1. The bit line contact 183 may include a first layer 183a and a second layer 183b. The first layer 183a may be disposed along a surface of the groove H1 and the second layer 183b may fill the bit line contact 183. However, this is just an example, and the bit line contact 183 may be formed of a single layer containing a single material. The bit line contact 183 may contain one or more of polycrystalline silicon, tungsten, and TIN. When the second layer 183b of the bit line contact 183 contains tungsten, the first layer 183a may contain TiN. Through this, the first layer 183a can limit and/or prevent tungsten of the second layer 183b from diffusing into the channel insulation layer 134. However, this is only an example, and the present disclosure is not limited thereto.

As shown in FIG. 2, one side of the bit line contact 183 along the X-axis direction may not contact the channel insulation layer 134, and the other side of the bit line contact 183 may contact the channel insulation layer 134. This is a structure derived from the manufacturing process, and the specific manufacturing method will be described later.

As shown in FIG. 2 and FIG. 3, one end of the bit line contact 183 along the Z-axis direction is in contact with the contact via 182 and the other end is in contact with the channel structure CH. Accordingly, the bit line 181 and the channel structure CH may be electrically connected through the bit line contact 183 and the contact via 182.

In some example embodiments, simultaneously referring to FIG. 1, a diameter R1 of the bit line contact 183 may be larger than a diameter R2 of the channel structure CH that is in contact with the bit line contact 183. That is, on a plane, the bit line contact 183 and the channel structure CH may have a circular shape, and in some example embodiments, the diameter R1 of the bit line contact 183 may be larger than the diameter R2 of the channel structure CH. Accordingly, the bit line contact 183 may be used as a mask to protect the channel structure CH during the formation process of the separation pattern 170. Therefore, the problem of the gate electrode 130 around the channel structure CH being removed due to an alignment error during the formation of the separation pattern 170 may be limited and/or prevented. The bit line contact 183 may be formed simultaneously when forming the channel structure CH.

In this way, the channel structure CH and the bit line contact 183 are formed as one process, and when the bit line contact 183 is used as a mask in the formation process of the separation pattern 170, the misalignment of the bit line contact 183 and the channel structure CH can be reduced (and/or minimized), and since the bit line contact 183 with a large diameter covers one side of the channel structure CH, the problem of the gate electrode 130 around the channel structure CH being removed due to an alignment error during the formation of the separation pattern 170 can be solved to improve reliability of the semiconductor device including the memory cell structure. A specific manufacturing method and effects will be described separately later.

Referring to FIG. 1 to FIG. 3, the bit line contact 183 in a region where the separation pattern 170 is formed may be partially removed. This means that the bit line contact 183 that is not in contact with the separation pattern 170 has a circular shape on a plane, but the bit line contact 183 that is in contact with the separation pattern 170 may not have a circular shape on a plane because a portion of the bit line contact 183 is etched. As shown in FIG. 1, some regions of the bit line contact 183 that contact the separation pattern 170 may form a part of the circular shape, and some other regions may not form a part of the circular shape. As described above, this is a structure derived because the bit line contact 183 is used as a mask covering one side of the channel structure CH during the formation process of the separation pattern 170. A detailed manufacturing method will be described separately later.

Referring to FIG. 2, the bit line contact 183 is also disposed on one end of the separation structure 160 (e.g., below the gate stacking structure 120 along the Z-axis direction as shown in FIG. 2). As will be described separately later, the bit line contact 183 disposed on one end of the separation structure 160 is formed through the same process as the bit line contact 183 disposed on one end of the channel structure and may include the same material. However, since the inside of the separation structure 160 contains an insulating material, the bit line contact 183 disposed on one end of the separation structure 160 may not electrically connect the bit line 181 and the separation structure 160. For example, the bit line contact 183 disposed on one end of the separation structure 160 may not substantially perform the function of contact.

Referring to FIG. 2, a common source electrode 112 may be disposed on the other end of the gate stacking structure 120 (e.g., above the gate stacking structure 120 along the Z-axis direction as shown in FIG. 2). The common source electrode 112 may be in contact with the second semiconductor pattern 147 of the channel structure CH. As shown in FIG. 2, the second semiconductor pattern 147 may be disposed at the other end of the separation structure 160 and be in contact with the common source electrode 112, but they are insulated from each other by a third layer 163 disposed between the first semiconductor pattern 146 and the second semiconductor pattern 147 that are disposed at both ends of the separation structure 160. The common source electrode 112 may be provided as a common source line (e.g., CSL in FIG. 26) of a non-volatile memory device. The common source electrode 112 may include, for example, impurity doped polycrystalline silicon, a metal, or a combination thereof, but is not limited thereto.

Although it is not illustrated in FIG. 2, another semiconductor structure including a cell region may be stacked on the common source electrode 112. In some example embodiments, the common source electrode 112 of the semiconductor structure shown in FIG. 2 and a common source electrode of the another semiconductor structure may be stacked to face each other, and the common source electrodes 112 of the respective semiconductor structures may be connected to each other. Such a connection may be established using a copper pad. This is an example, and the schematic connection form is shown as a 2-1 structure 4200a and a 2-2 structure 4200b in FIG. 28, but is not limited thereto.

As described above, in the semiconductor device according to some example embodiments, the width of the channel structure CH has a shape that decreases as it moves away from the common source electrode 112 and as it approaches the bit line contact 183, and one end of the channel structure CH disposed furthest from the common source electrode 112 is in contact with the bit line contact 183 having a larger diameter than the channel structure CH. Since the bit line contact 183 may be formed through the same process when forming the channel structure CH, misalignment can be limited and/or prevented, and during the process of forming the separation pattern 170, the bit line contact 183 may function as a mask that protects the channel structure CH. In FIG. 2 and FIG. 3, a configuration in which the channel structure CH, the bit line contact 183, the contact via 182, and the bit line 181 are connected is shown, but in some example embodiments, an auxiliary contact may be included between the bit line contact 183 and the contact via 182.

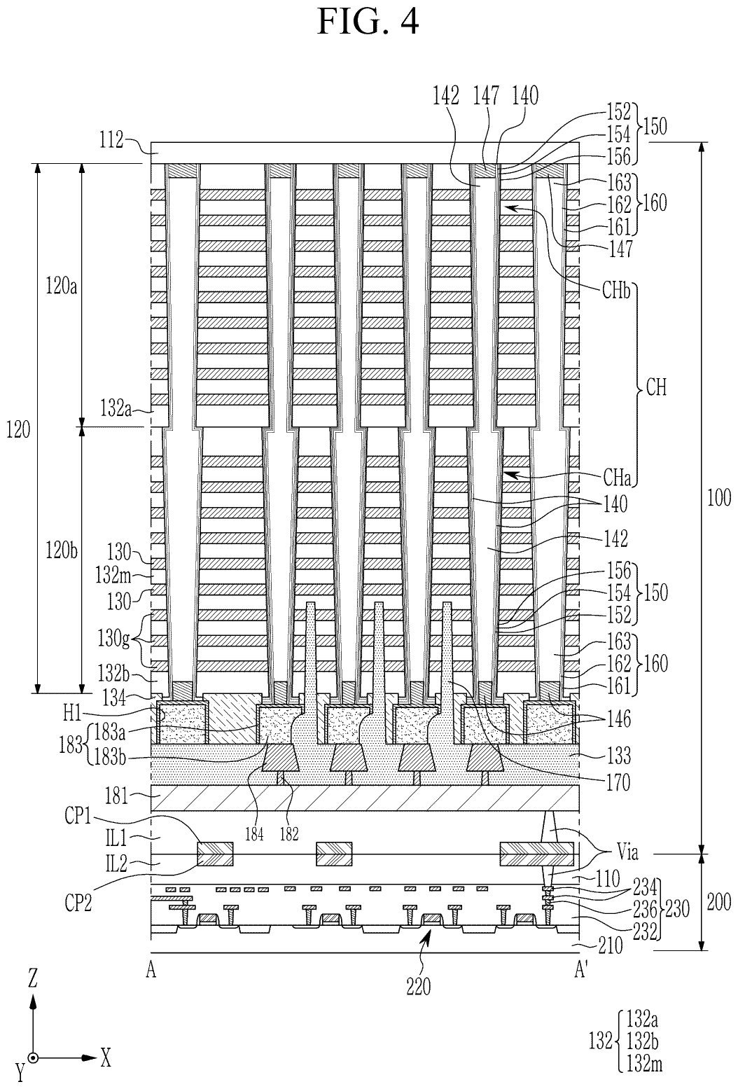

FIG. 4 shows a cross-sectional view taken along line A-A′ according to some example embodiments. Referring to FIG. 4, a semiconductor device according to some example embodiments is the same as the semiconductor device according to some example embodiments of FIG. 2, except that an auxiliary contact 184 is further included as disposed between the bit line contact 183 and the contact via 182. Detailed descriptions of the same components are omitted.

Referring to FIG. 4, the semiconductor device according to the some example embodiments further includes an auxiliary contact 184 disposed between a bit line contact 183 and a contact via 182. The auxiliary contact 184 may include a metal, for example, tungsten, but is not limited thereto. When the auxiliary contact 184 is included as in FIG. 4, misalignment can be reduced. For example, the probability of misalignment can be reduced when the auxiliary contact 184 is disposed between the bit line contact 183 and the contact via 182, rather than when the bit line contact 183 and the contact via 182 are in direct contact, and even if misalignment occurs, the bit line contact 183 and the contact via 182 may be connected stably.

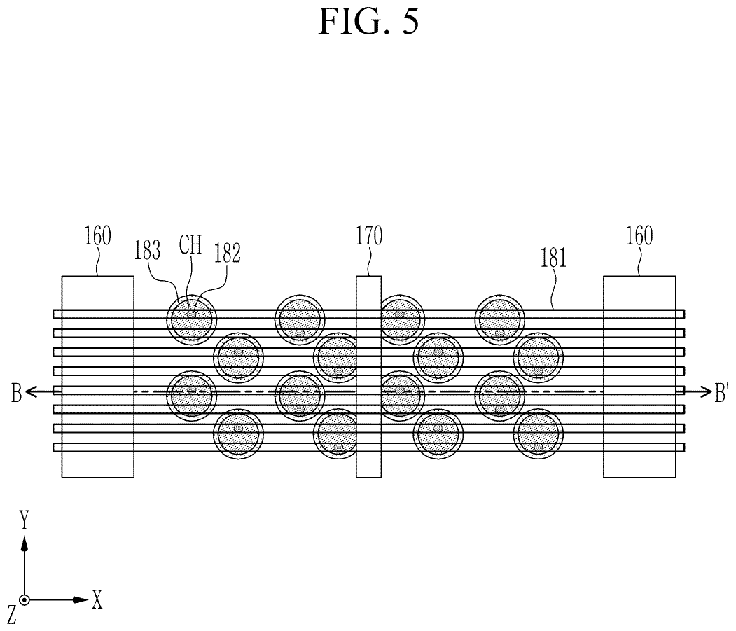

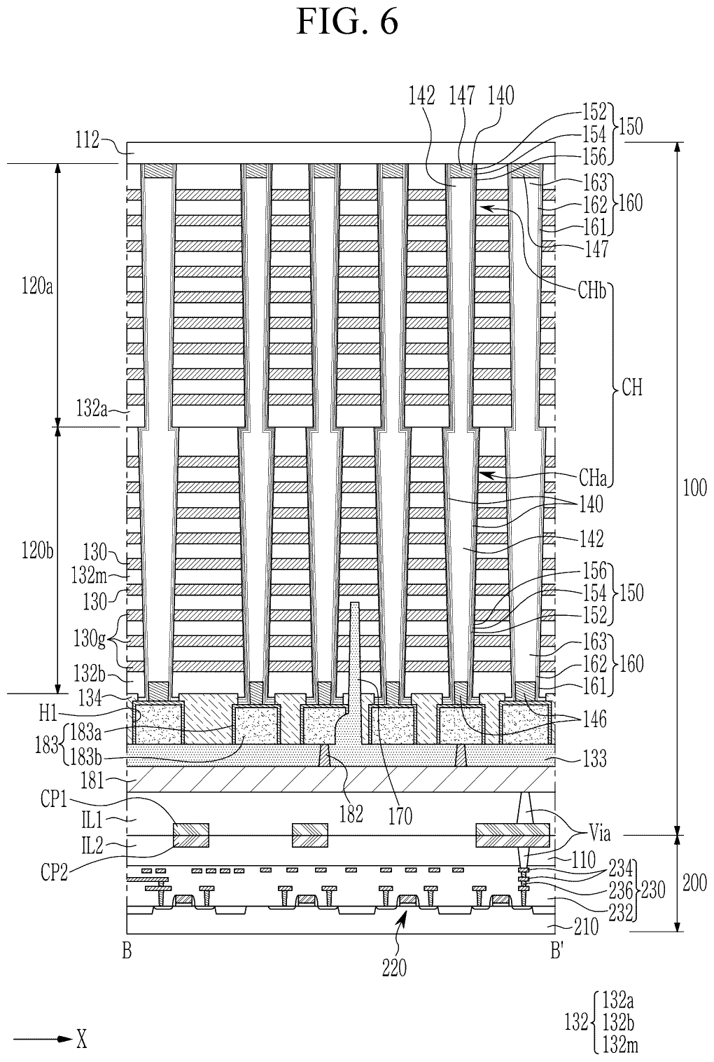

Hereinafter, a semiconductor device according to some example embodiments will be described with reference to FIG. 5. FIG. 5 is a schematic top plan of a semiconductor device according to some example embodiments. FIG. 6 shows a cross-sectional view of the semiconductor device of FIG. 5, taken along the line B-B′.

Referring to FIG. 5, a semiconductor device according to some example embodiments is the same as the semiconductor device according to some example embodiments of FIG. 1, except that the number of bit lines 181 is doubled, and the number of spaces partitioned by a separation pattern 170 between separation structures 160 is ½. Detailed descriptions of the same components are omitted.

In some example embodiments of FIG. 1, a plurality of channel structures CH are in contact with one bit line 181, and each channel structure CH in contact with the same bit line 181 is separated by a separation pattern 170. That is, the plurality of channel structures CH disposed between the separation structure 160 and the separation pattern 170, or between the separation pattern 170 and the separation pattern 170 are connected to different bit lines 181, respectively.

Likewise, in some example embodiments of FIG. 5, the plurality of channel structures CH disposed between the separation structure 160 and the separation pattern 170 are in contact with different bit lines 181.

In some example embodiments of FIG. 5, two channel structures CH overlap each other with one bit line 181 in a region between the separation structure 160 and the separation pattern 170. However, each channel structure CH is in contact with a different bit line 181 through a contact via 182. Accordingly, in some example embodiments of FIG. 5, the plurality of channel structures CH disposed between the separation structure 160 and the separation pattern 170 are connected with different bit lines 181.

FIG. 6 is a cross-sectional view of FIG. 5, taken along the line B-B′. Referring to FIG. 6, the semiconductor device according to some example embodiments is the same as the semiconductor device according to some example embodiments of FIG. 2, except that two channel structures CH are disposed between the separation structure 160 and the separation pattern 170. Detailed descriptions of the same components are omitted. Referring to FIG. 6, one of the two channel structures CH between the separation structure 160 and the separation pattern 170. In FIG. 6, the channel structure CH that is not connected to the bit line 181 may be connected to a different bit line 181 as shown in FIG. 5.

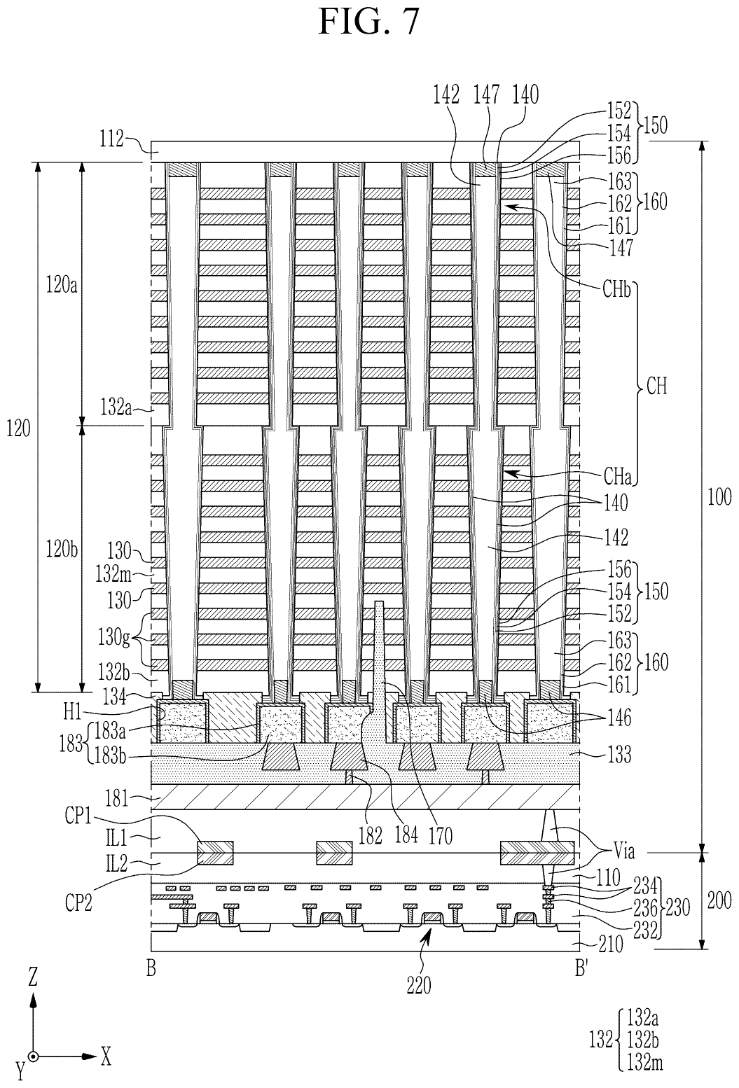

FIG. 7 shows the same cross-sectional view as FIG. 6 according to some example embodiments. Referring to FIG. 7, a semiconductor device according to some example embodiments is the same as the semiconductor device according to some example embodiments of FIG. 6, except that an auxiliary contact 184 disposed between a bit line contact 183 and a contact via 182 is further included. Detailed descriptions of the same components are omitted. Referring to FIG. 7, the semiconductor device according to some example embodiments includes the auxiliary contact 184 disposed between the bit line contact 183 and the contact via 182. The auxiliary contact 184 may include a metal, for example, tungsten, but is not limited thereto. When the auxiliary contact 184 is included, misalignment can be reduced. For example, the probability of misalignment can be reduced when the auxiliary contact 184 is disposed between the bit line contact 183 and the contact via 182, rather than when the bit line contact 183 and the contact via 182 are in direct contact, and even if misalignment occurs, the bit line contact 183 and the contact via 182 may be connected stably.

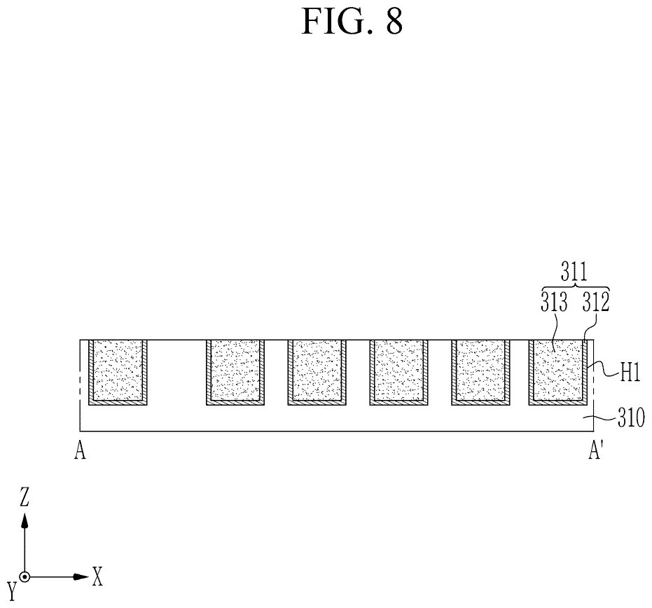

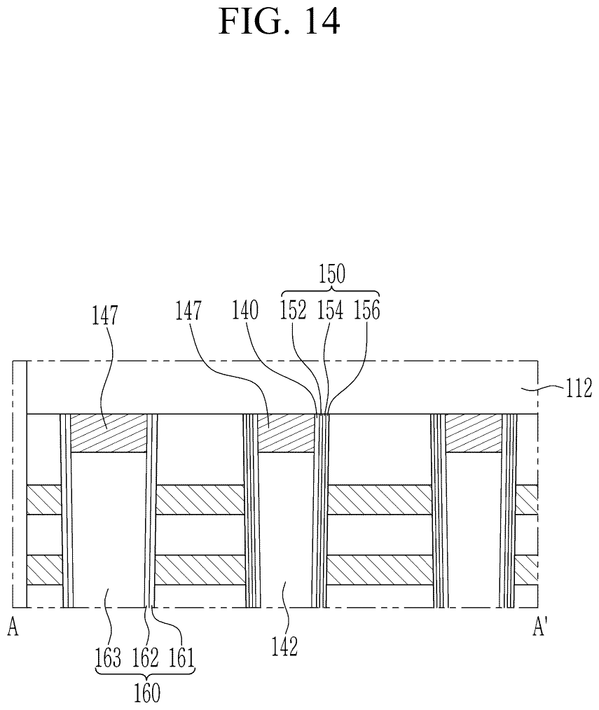

Hereinafter, referring to FIG. 8 to FIG. 25, a manufacturing method of a semiconductor device according to some example embodiments will be described. FIG. 8 to FIG. 25 show a manufacturing process according to some example embodiments. FIG. 8 to FIG. 13 and FIG. 15 to FIG. 25 illustrate a manufacturing method including the region marked by A in FIG. 2 for better comprehension and ease of description. FIG. 14 shows a manufacturing method of the region marked by B in FIG. 2 for better comprehension and ease of description.

First, referring to FIG. 8, an etch stopper 311 is formed in an auxiliary substrate 310.

The etch stopper 311 may be formed by forming a groove H1 in the auxiliary substrate 310 and filling the groove H1 of the auxiliary substrate 310. As shown in FIG. 8, the etch stopper 311 may include a first layer 312 and a second layer 313. The first layer 312 is disposed along a surface of the groove H1 of the auxiliary substrate 310 and the second layer 313 may fill the groove H1. However, this is an example, and the present disclosure is not limited to this. The etch stopper 311 may be formed as a single layer. The etch stopper 311 may contain one or more of polycrystalline silicon, tungsten, TiN, and carbon. When the second layer 313 of the etch stopper 311 contains tungsten, the first layer 312 may contain TiN. In some example embodiments, the first layer 312 containing TiN may limit and/or prevent diffusion of tungsten in the second layer 313. However, when the etch stopper 311 contains polycrystalline silicon, TiN, or carbon, the etch stopper 311 may be made of a single layer.

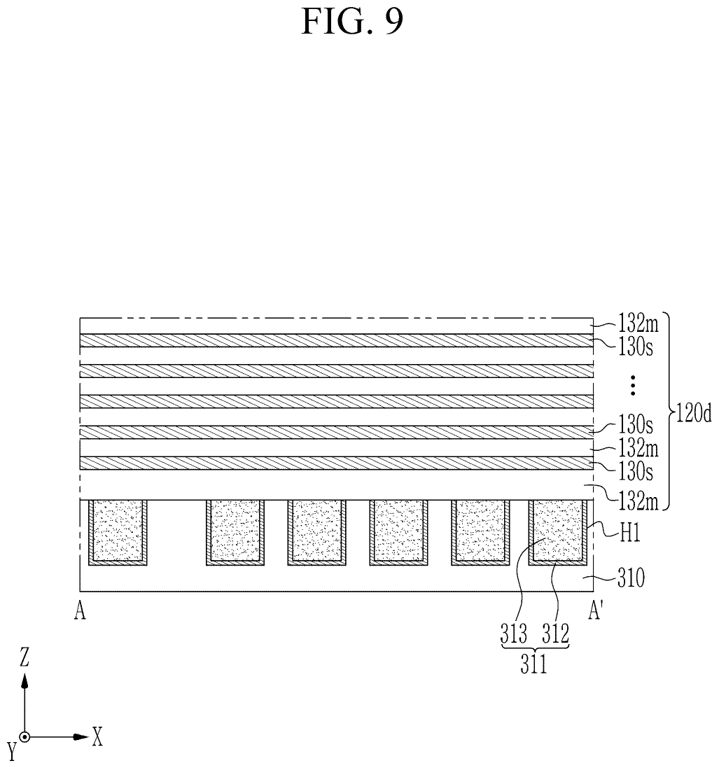

Next, referring to FIG. 9, a plurality of interlayer insulation layers 132m and a plurality of sacrificial insulation layers 130s are alternately stacked on the auxiliary substrate 310 to form a first stacking structure 120d. The interlayer insulation layer 132m may include silicon oxide, silicon nitride, silicon oxynitride, a low dielectric constant material, and the like, and the sacrificial insulation layer 130s may include at least one of silicon, silicon oxide, silicon carbide, and silicon nitride, but may be formed of a different material from the interlayer insulation layer 132m. For example, the interlayer insulation layer 132m may include silicon oxide, and the sacrificial insulation layer 130s may include silicon nitride. The sacrificial insulation layer 130s may be a layer that is replaced with a gate electrode (refer to 130 in FIG. 2) in the subsequent process. For example, the sacrificial insulation layer 130s may be formed to correspond to a part where the gate electrode (refer to 130 in FIG. 2) will be formed.

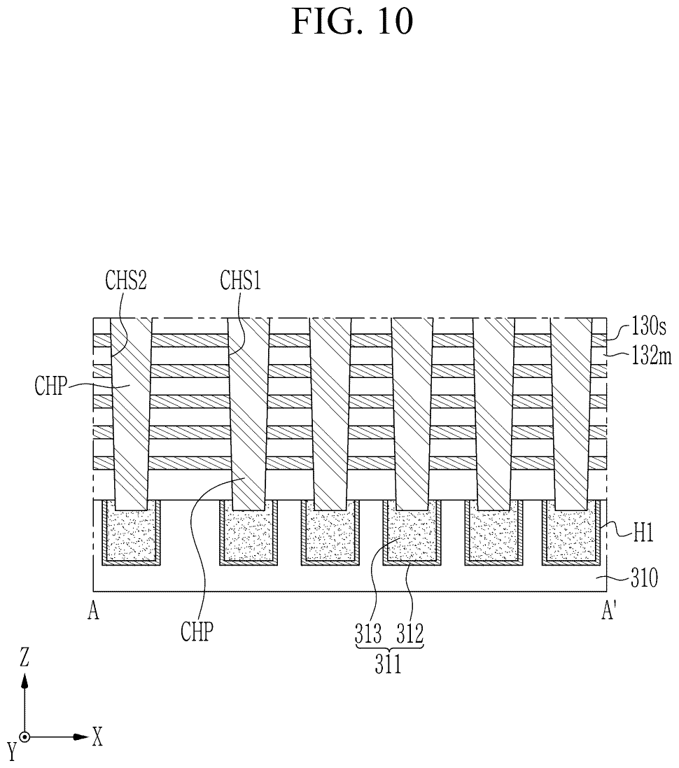

Next, referring to FIG. 10, the first stacking structure 120d is patterned to form a first sub-hole CHS1 and a second sub-hole CHS2 that penetrate the first stacking structure 120d while overlapping each etch stopper 311. The first sub-hole CHS1 is a region where the channel structure CH is later formed, and the second sub-hole CHS2 is a region where the separation structure 160 is later formed. In FIG. 10, the cross-section of the first sub-hole CHS1 and the second sub-hole CHS2 is illustrated, and the planar shape of the first sub-hole CHS1 may be a circle that is similar to the shape of the channel structure CH shown in FIG. 1 and the planar shape of the second sub-hole CHS may be a shape extending in the second direction (Y-axis direction) like the separation structure 160 shown in FIG. 1.

The first sub-hole CHS1 and the second sub-hole CHS2 are formed while overlapping the etch stopper 311 and the etch stopper 311 may be partially etched due to forming of the first sub-hole CHS1 and the second sub-hole CHS2. In the present stage, the first sub-hole CHS1 and the second sub-hole CHS2 may be filled with a sacrificial layer CHP. The sacrificial layer CHP filled in the first sub-hole CHS1 and the second sub-hole CHS2 may include polysilicon or carbon-based materials. However, the material of the sacrificial layer CHP is not limited to this and may be changed in various ways.

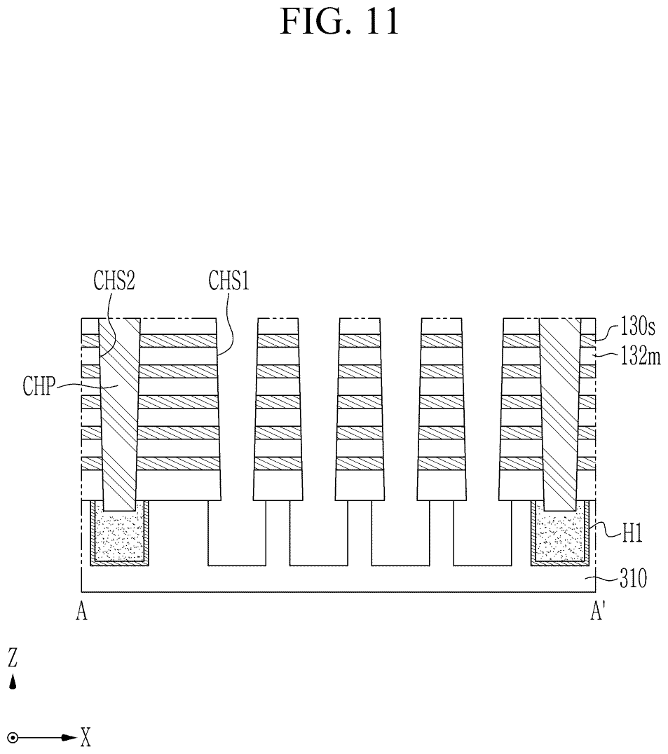

Next, referring to FIG. 11, the sacrificial layer CHP filled in the first sub-hole CHS1 and the etch stopper 311 are removed.

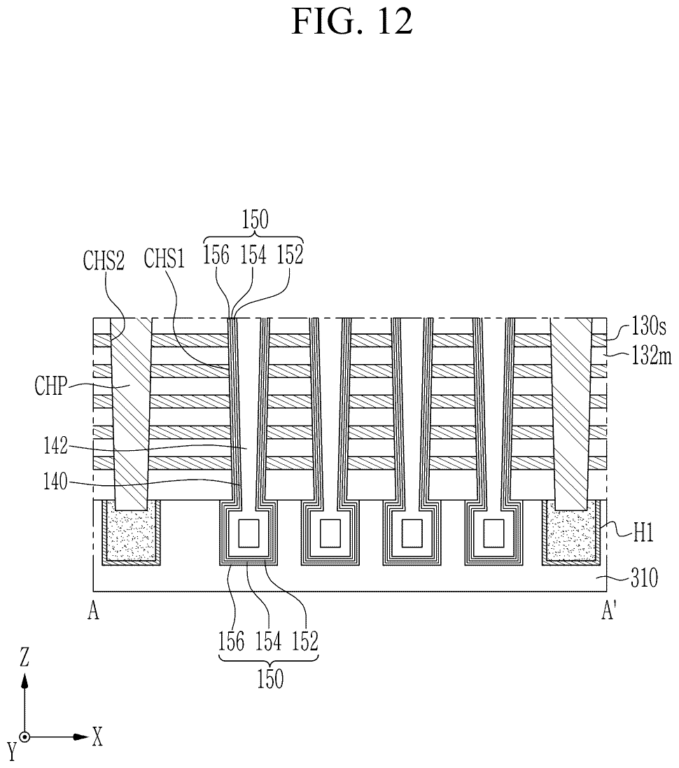

Next, referring to FIG. 12, a gate dielectric layer 150, a channel layer 140, and a core insulation layer 142 are formed in the first sub-hole CHS1 from which the sacrificial layer CHP and the etch stopper 311 are removed.

The gate dielectric layer 150 may include a tunneling layer 152, a charge storage layer 154, and a blocking layer 156. The tunneling layer 152 may include an insulating material (e.g., silicon oxide, silicon oxynitride, and the like) capable of charge tunneling. The charge storage layer 154 may be used as a data storage region, and the charge storage layer 154 may include polycrystalline silicon, silicon nitride, and the like. The blocking layer 156 may include an insulating material that can limit and/or prevent undesired charge inflow into the gate electrode 130. For example, the blocking layer 156 may include silicon oxide, silicon nitride, silicon oxynitride, a high dielectric constant material having a dielectric constant higher than silicon oxide, or a combination thereof. For example, the tunneling layer 152 may include silicon oxide, the charge storage layer 154 may include silicon nitride, and the blocking layer 156 may include silicon oxide. However, this is only an example, and the present disclosure is not limited thereto.

The channel layer 140 may include a semiconductor material, for example, monocrystalline silicon or polycrystalline silicon. The core insulation layer 142 may include various insulating materials. For example, the core insulation layer 142 may include silicon oxide, silicon nitride, silicon oxynitride, or a combination thereof. The core insulation layer 142 may fill a space inside the first sub-hole CHS1. In the groove H1 where the etch stopper has been removed, the core insulation layer 142 may not completely fill the groove H1 and a void may be formed.

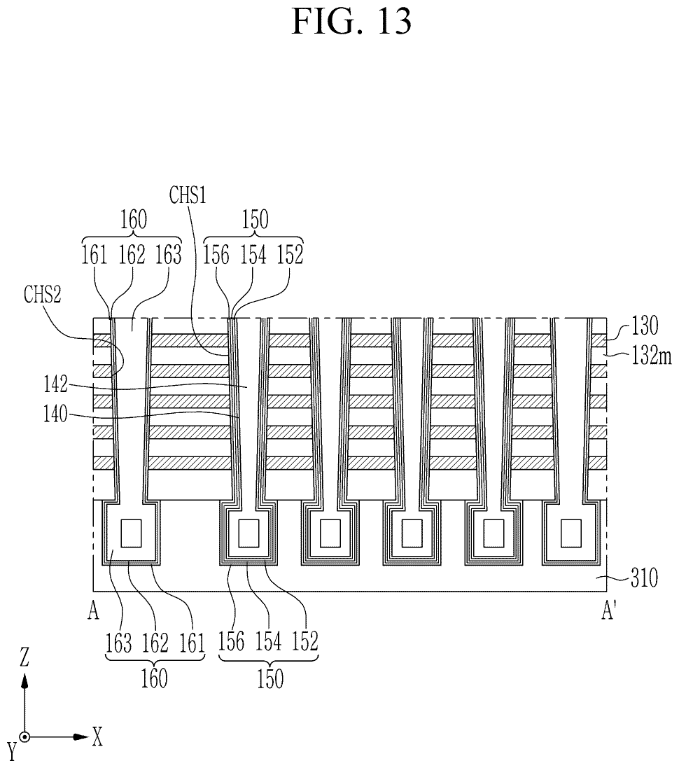

Next, referring to FIG. 13, the sacrificial layer CHP and the etch stopper 311 filled in the second sub-hole CHS2 are removed, and the sacrificial insulation layer 130s is selectively removed and the gate electrode 130 is formed through a removed space. For example, the sacrificial insulation layer 130s is removed, and the gate electrode 130 may be formed in the space where the sacrificial insulation layer 130s is removed. That is, the sacrificial insulation layer 130s is removed using an etching process, and then a metal material such as tungsten (W), copper (Cu), aluminum (Al), molybdenum (Mo), and the like is deposited, thereby forming the gate electrode 130.

Next, the first layer 161, the second layer 162, and the third layer 163 are formed in the second sub-hole CHS2. The first layer 161 may include silicon oxide, the second layer 162 may include silicon nitride, and the third layer 163 may include silicon oxide, but this is just an example, and the present disclosure is not limited thereto. The first layer 161 filling the second sub-hole CHS2 may include the same material as the blocking layer 156 filling the first sub-hole CHS1, the second layer 162 filling the second sub-hole CHS2 may include the same material as the charge storage layer 154 filling the first sub-hole CHS1, and the third layer 163 filling the second sub-hole CHS2 may include the same material as the tunneling layer 152 filling the first sub-hole CHS1. However, this is an example, and the present disclosure is not limited thereto.

The third layer 163 may fill the space inside the second sub-hole CHS2. In the groove H1 where the etch stopper has been removed, the third layer 163 may not completely fill the groove H1 and a void may be formed.

Hereafter, for better comprehension and ease of description, the processing of the part B of FIG. 2 will be described. FIG. 14 shows processing of the part B of FIG. 13 after the processing of FIG. 13 has progressed. That is, after the processing of FIG. 13 has progressed, the core insulation layer 142 in the first sub-hole CHS1 and the third layer 163 in the second sub-hole CHS2 may be partially removed in a region corresponding to the part B of FIG. 2. Next, the second semiconductor pattern 147 may be formed in the region where the core insulation layer 142 inside the first sub-hole CHS1 and the third layer 163 inside the second sub-hole CHS2 have been removed. The second semiconductor pattern 147 may include epitaxial silicon, epitaxial germanium, polycrystalline silicon, monocrystalline silicon, polycrystalline germanium, or monocrystalline germanium with or without dopant. For example, the second semiconductor pattern 147 may include N+ doped polycrystalline silicon.

Next, the common source electrode 112 is formed. The common source electrode 112 may be in contact with the second semiconductor pattern 147 of the channel structure CH. The common source electrode 112 may be provided as a common source line (e.g., CSL in FIG. 26) of a non-volatile memory device. The common source electrode 112 may include, for example, impurity doped polycrystalline silicon, metal, or a combination thereof, but is not limited thereto. Although it is illustrated in FIG. 14 that the second semiconductor pattern 147 and the common source electrode 112 are directly in contact with each other, this is just an example, and a separate contact may be disposed between the second semiconductor pattern 147 and the common source electrode 112 and the second semiconductor pattern 147 and the common source electrode 112 may be connected through this contact.

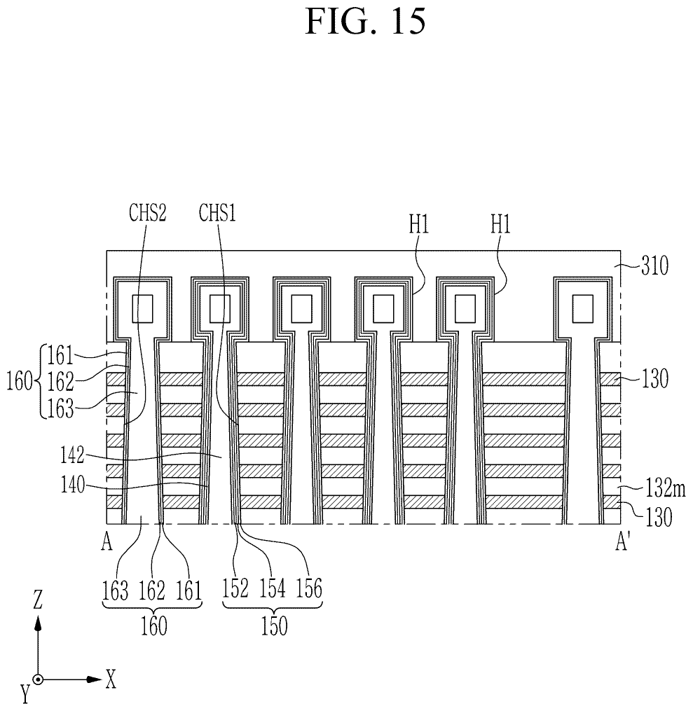

Next, the subsequent process will be described with reference to FIG. 15. FIG. 15 is the same region as the region shown in FIG. 8 to FIG. 13, that is the region including A in FIG. 2. Next, referring to FIG. 15, the structure is flipped. In this operation, the common source electrode 112 of the flipped structure may be bonded to a common source electrode 112 of another structure including the gate electrode structure. This is an example, and the schematic bonding form is described as the 2-1 structure 4200a and the 2-2 structure 4200b in FIG. 28, but is not limited thereto.

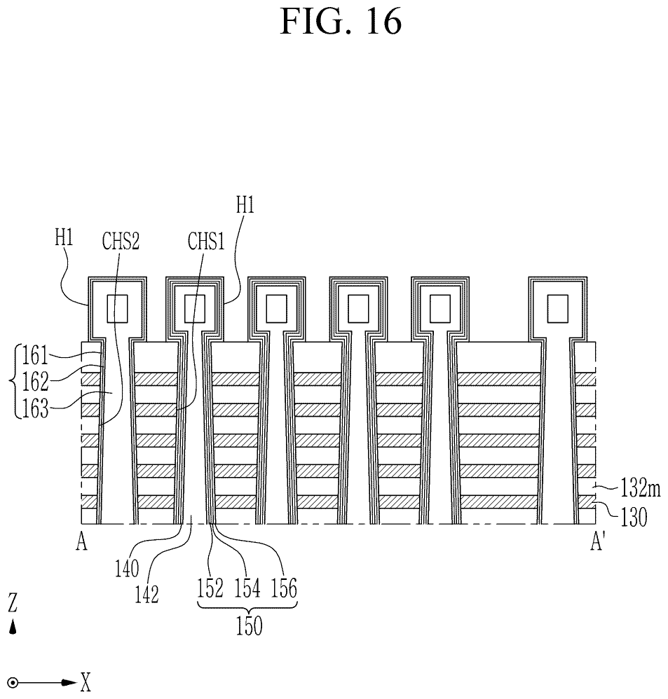

Next, referring to FIG. 16, the auxiliary substrate 310 is removed. The removal of the auxiliary substrate 310 may be accomplished by grinding an upper surface of the auxiliary substrate 310 and then removing the auxiliary substrate 310 disposed between the grooves H1 by dry etching. However, this is an example and the present disclosure is not limited thereto. The removal of the auxiliary substrate 310 may be accomplished using various methods.

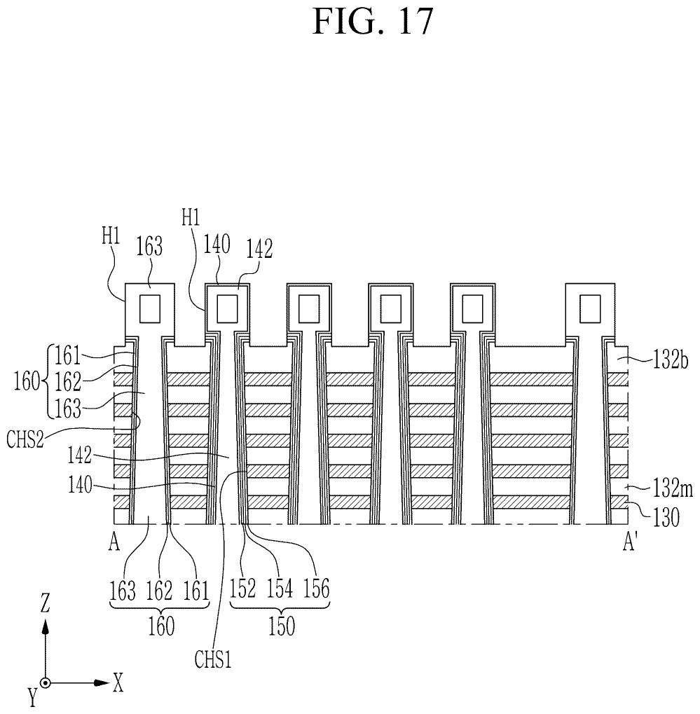

Next, referring to FIG. 17, the first layer 161, the second layer 162, and the third layer 163 formed in the groove H1 above the second sub-hole CHS2 are removed. Likewise, the tunneling layer 152, the charge storage layer 154, and the blocking layer 156 formed in the groove H1 above the first sub-hole CHS1 are removed. In this process, the first layer 161 and the second layer 162 disposed in the groove H1 above the second sub-hole CHS2 are removed, and the third layer 163 is also partially removed, and thus a thickness becomes thinner and the third layer 163 can be exposed.

Likewise, the tunneling layer 152, the charge storage layer 154, and the blocking layer 156 formed in the groove H1 above the first sub-hole CHS1 are removed such that the channel layer 140 is exposed. In this stage, a part of the upper insulation layer 132b may be etched and thus a thickness may become thinner.

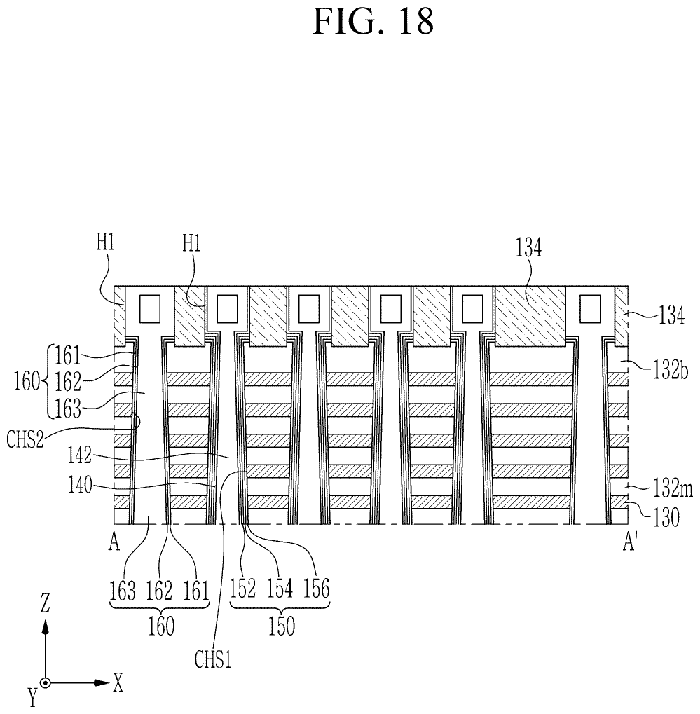

Next, referring to FIG. 18, the channel insulation layer 134 is formed. The channel insulation layer 134 may include silicon nitride or silicon oxidation nitride. The channel insulation layer 134 may fill a space between the groove H1 above the second sub-hole CHS2 and the groove H1 above the first sub-hole CHS1. Next, the channel layer 140 disposed on the upper surface of the groove H1 above the first sub-hole CHS1 is removed. In this stage, the core insulation layer 142 may be exposed through the upper surface of the groove H1.

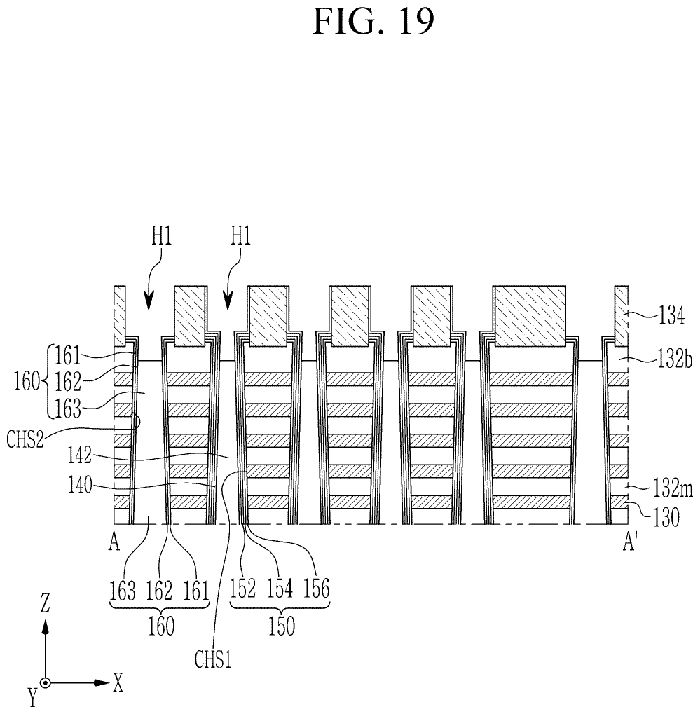

Next, referring to FIG. 19, the core insulation layer 142 disposed inside the groove H1 above the first sub-hole CHS1 and the third layer 163 disposed inside the groove H1 above the second sub-hole CHS2 are removed. In this process, the core insulation layer 142 disposed inside the groove H1 above the first sub-hole CHS1 is removed, and the core insulation layer 142 disposed inside the first sub-hole CHS1 is partially removed. Likewise, the third layer 163 disposed inside the groove H1 above the second sub-hole CHS2 is removed, and the third layer 163 disposed inside the second sub-hole CHS2 is partially removed.

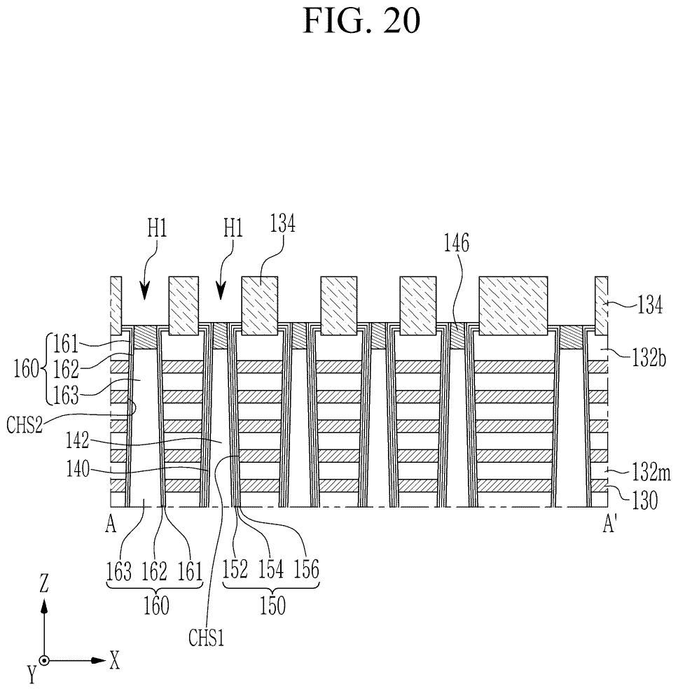

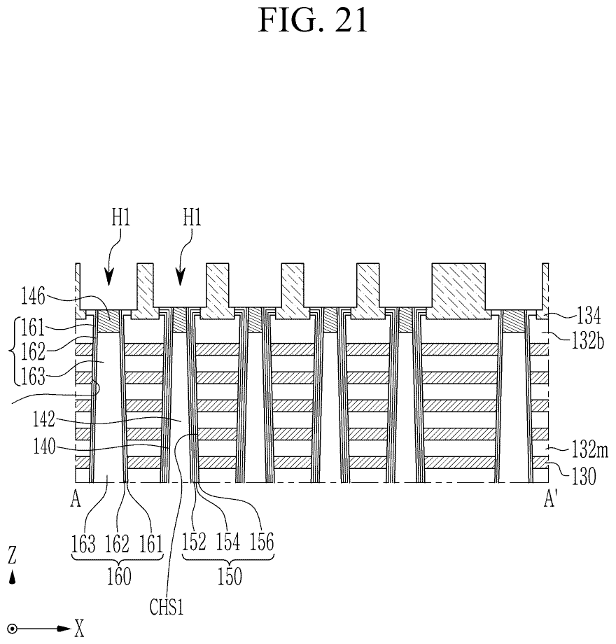

Next, referring to FIG. 20, the semiconductor pattern 146 is formed in a region where the core insulation layer 142 in the first sub-hole CHS1 is removed and a region where the third layer 163 in the second sub-hole CHS2 is removed. The description of the material of the first semiconductor pattern 146 is omitted as it is the same as previously described. In some example embodiments, in the present stage, the first semiconductor pattern 146 may be deposited inside the groove H1, the region where the core insulation layer 142 inside the first sub-hole CHS1 is removed, and the entire region where the third layer 163 inside the second sub-hole CHS2 is removed. Next, the first semiconductor pattern 146 formed inside the groove H1 is removed through a process of etching the deposited semiconductor pattern 146, and the first semiconductor pattern 146 disposed inside the region where the core insulation layer 142 inside the first sub-hole CHS1 is removed and the region where the third layer 163 inside the second sub-hole CHS2 is removed may remain. Through this process, as shown in FIG. 20, the first semiconductor pattern 146 may be formed in the region where the core insulation layer 142 inside the first sub-hole CHS1 is removed and the region where the third layer 163 inside the second sub-hole CHS2 is removed. Next, referring to FIG. 21, a width of the groove H1 between the channel insulation layers 134 is expanded by etching the channel insulation layer 134. Through this, it is possible to form a bit line contact with a width wider than the channel structure CH at a later stage. However, this is only an example, and this operation may be omitted.

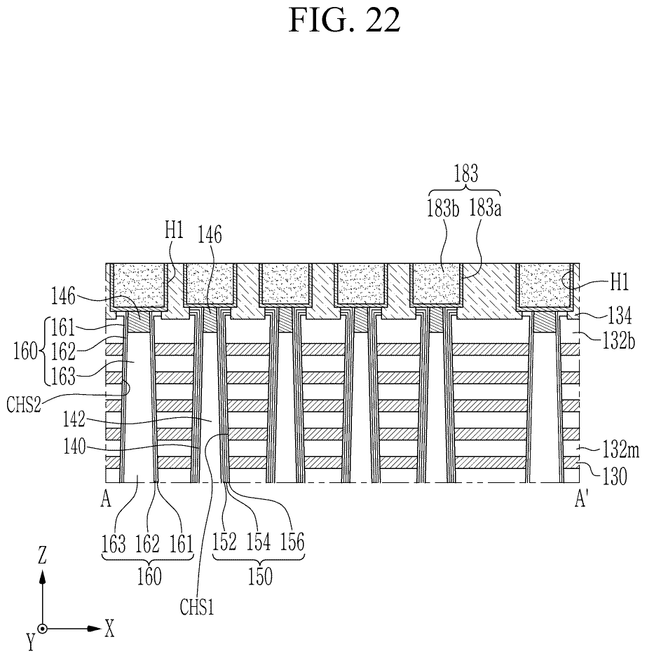

Next, referring to FIG. 22, the bit line contact 183 is formed in the groove H1 between the channel insulation layers 134. The bit line contact 183 may include a first layer 183a and a second layer 183b. The first layer 183a may be disposed along the surface of the groove H1 and the second layer 183b may fill an inner space of the groove H1. However, in some example embodiments, the bit line contact 183 may be formed of a single layer containing a single material. The bit line contact 183 may include one or more of polycrystalline silicon, tungsten, and TIN. When the second layer 183b of the bit line contact 183 contains tungsten, the first layer 183a may contain TiN. This limits and/or prevents tungsten from diffusing into the channel insulation layer 134. However, this is only an example, and the present disclosure is not limited thereto.

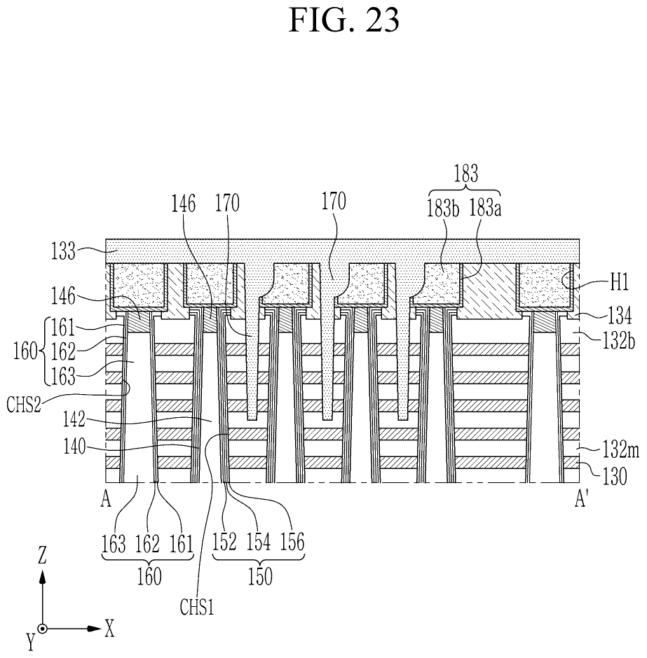

Next, referring to FIG. 23, a separation pattern 170 is formed. The separation pattern 170 may be formed to penetrate the channel insulation layer 134 and penetrate some layers of the cell insulation layer 132 and the gate electrode 130. To form the separation pattern 170, the channel insulation layer 134 and the cell insulation layer 132 may be etched first. During the subsequent etching process of gate electrode 130, the bit line contact 183 may be partially etched. Since an upper surface of the channel structure CH is covered by the bit line contact 183 having a larger area than the channel structure CH, the channel structure CH of the gate electrode 130 for forming the separation pattern 170 can be protected.

In this process, the bit line contact 183 may be partially removed. Therefore, a planar shape of the bit line contact 183 may have some regions formed of a part of a circular shape and some regions may have a shape other than a circular shape. That is, as shown in FIG. 1, the bit line contact 183 may have a shape other than a circle in a region adjacent to the separation pattern 170.

As shown in FIG. 23, the bit line insulation layer 133 may be formed on an upper portion of the bit line contact 183, and the bit line insulation layer 133 and the separation pattern 170 may be connected through a groove penetrating the channel insulation layer 134 and integrally formed.

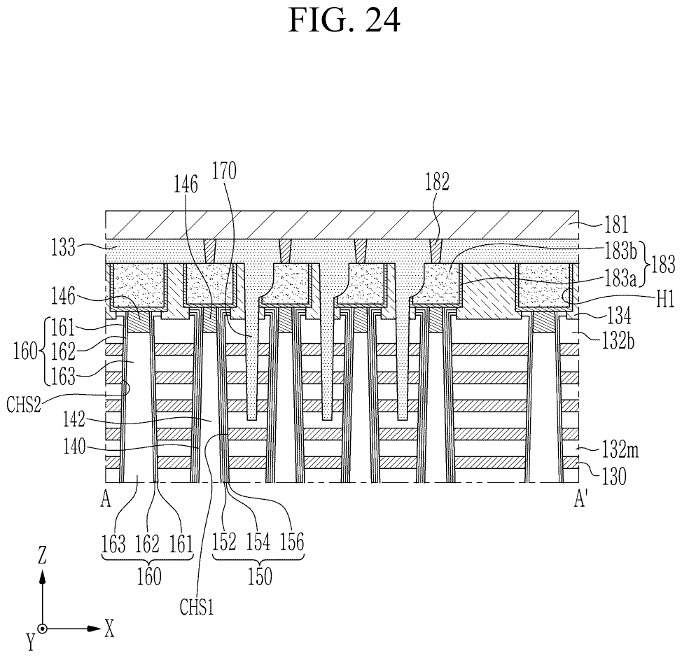

Next, referring to FIG. 24, a contact via 182 that is in contact with the bit line contact 183 is formed in the bit line insulation layer 133, and a bit line 181 is formed above the bit line insulation layer 133. The bit line 181 may be electrically connected with the channel structure CH through the contact via 182 and the bit line contact 183.

FIG. 24 shows a configuration in which the channel structure CH, the bit line contact 183, the contact via 182, and the bit line 181 are connected, but some example embodiments may further include a process for forming an auxiliary contact 184.

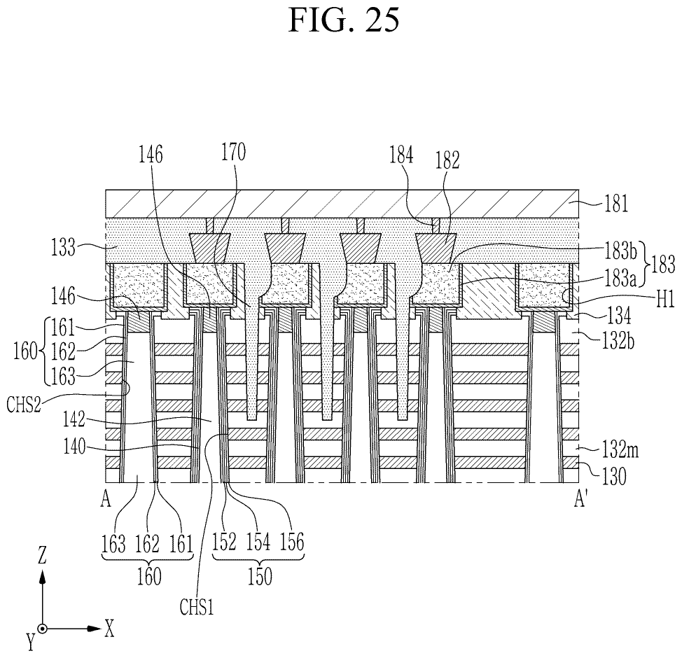

For example, referring to FIG. 25, in some example embodiments, after the processing of FIG. 23 and instead of the processing of FIG. 24, the auxiliary contact 184 is formed on the bit line contact 183, the contact via 182 is formed, and the bit line 181 may be formed above the bit line insulation layer 133. Through this process, a semiconductor device including the bit line contact 183 and the auxiliary contact 184 may be manufactured.

An example of an electronic system including the semiconductor device described above will be described in detail as follows.

FIG. 26 schematically shows an electronic system including a semiconductor device according to some example embodiments.

Referring to FIG. 26, an electronic system 1000 according to some example embodiments may include a semiconductor device 1100 and a controller 1200 that is electrically connected with the semiconductor device 1100. The electronic system 1000 may be a storage device including one or a plurality of semiconductor devices 1100 or an electronic device including a storage device. For example, the electronic system 1000 may be a solid state drive device (SSD) device, a universal serial bus (USB), a computing system, a medical device, or a communication apparatus that includes one or a plurality of semiconductor devices 1100.

The semiconductor device 1100 may be a non-volatile memory device, for example, the NAND flash memory device described above. The semiconductor device 1100 may include a first structure 1100F and a second structure 1100S on the first structure 1100F. In some example embodiments, the first structure 1100F may be placed next to the second structure 1100S. The first structure 1100F may be a peripheral circuit structure including a decoder circuit 1110, a page buffer 1120, and a logic circuit 1130. The second structure 1100S may be a memory cell structure including a bit line BL, a common source line CSL, a word line WL, a first gate upper line UL1 and a second gate upper line UL2, a first gate lower line LL1 and a second gate lower line LL2, and a memory cell string CSTR between the bit line BL and the common source line CSL.

In the second structure 1100S, each memory cell string CSTR may include lower transistors LT1 and LT2 disposed adjacent to the common source line CSL, upper transistors UT1 and UT2 disposed adjacent to the bit line BL, and a plurality of memory cell transistors MCT disposed between the lower transistors LT1 and LT2 and the upper transistors UT1 and UT2. The number of lower transistors LT1 and LT2 and the number of upper transistors UT1 and UT2 may vary depending on some example embodiments.

In some example embodiments, the lower transistors LT1 and LT2 may include a ground selection transistor, and the upper transistors UT1 and UT2 may include a string selection transistor. The first gate lower line LL1 and the second gate lower line LL2 may be gate lines of the lower transistors LT1 and LT2, respectively. The word line WL may be a gate line of the memory cell transistor MCT, and the gate upper lines UL1 and UL2 may be gate lines of the upper transistors UT1 and UT2, respectively.

The common source line CSL, the first gate lower line LL1 and the second gate lower line LL2, the word line WL, and the first gate upper line UL1 and the second gate upper line UL2 may be electrically connected with the decoder circuit 1110 through a first connection wire 1115 extending to the second structure 1100S in the first structure 1100F. The bit line BL may be electrically connected to the page buffer 1120 through second connection wire 1125, which extends to the second structure 1100S in the first structure 1100F.

In the first structure 1100F, the decoder circuit 1110 and the page buffer 1120 may perform a control operation for at least one memory cell transistor among a plurality of memory cell transistors MCT. The decoder circuit 1110 and the page buffer 1120 may be controlled by the logic circuit 1130. The semiconductor device 1100 may communicate with the controller 1200 through an input/output pad 1101 electrically connected with the logic circuit 1130. The input/output pad 1101 may be electrically connected to the logic circuit 1130 through an input/output connection wire 1135 that extends from the first structure 1100F to the second structure 1100S.

The controller 1200 may include a processor 1210, a NAND controller 1220, and a host interface 1230. Depending on some example embodiments, the electronic system 1000 may include a plurality of semiconductor devices 1100, and in some example embodiments, the controller 1200 may control the plurality of semiconductor devices 1100.

The processor 1210 may control the overall operation of the electronic system 1000, including the controller 1200. The processor 1210 may operate according to desired (and/or alternatively predetermined) firmware and may access the semiconductor device 1100 by controlling the NAND controller 1220. The NAND controller 1220 may include a NAND interface 1221 that processes communication with the semiconductor device 1100. Through the NAND interface 1221, control instructions for controlling the semiconductor device 1100, data to be written to the memory cell transistor MCT of the semiconductor device 1100, data to be read from the memory cell transistor MCT of the semiconductor device 1100, and the like may be transmitted. The host interface 1230 may provide a communication function between the electronic system 1000 and an external host. When a control instruction is received from the external host through the host interface 1230, the processor 1210 may control the semiconductor device 1100 in response to the control instruction.

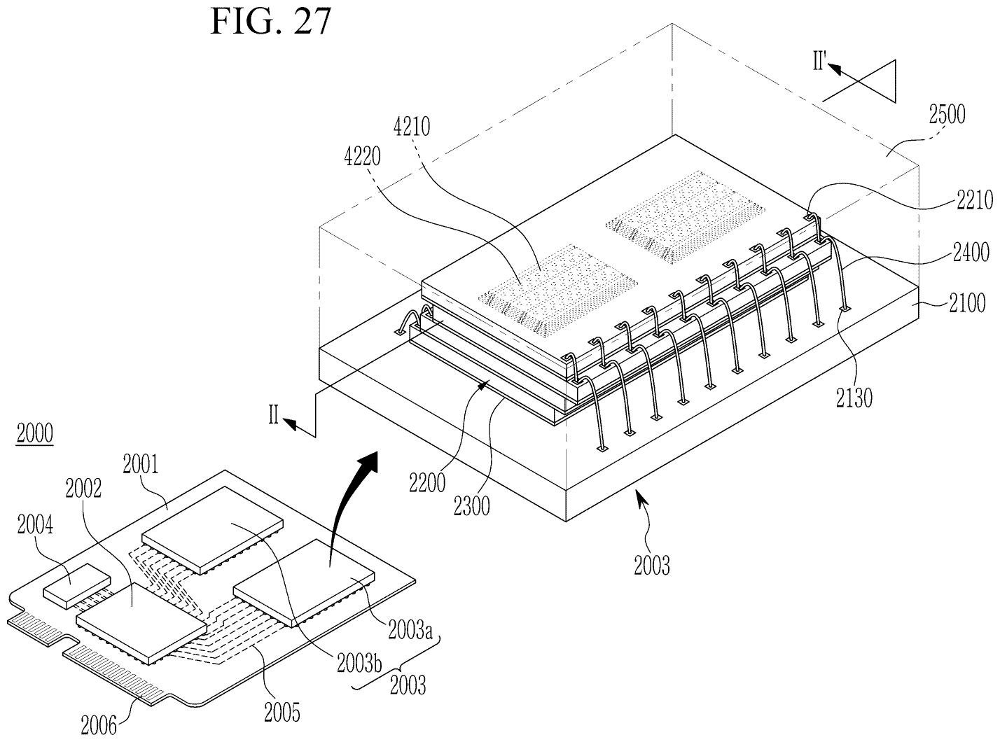

FIG. 27 is a perspective view that schematically shows an electronic system including the semiconductor device according to an some example embodiments. FIG. 28 conceptually shows a region cut from the semiconductor package 2003 of FIG. 27, taken along the line II-II′ for description of the semiconductor package 2003 of FIG. 27 according to some example embodiments.

Referring to FIG. 27, an electronic system 2000 according to some example embodiments may include a main substrate 2001, a controller 2002, one or more semiconductor packages 2003, and a DRAM 2004, which are mounted on the main substrate 2001. The semiconductor package 2003 and the DRAM 2004 may be connected with the controller 2002 by a wiring pattern 2005 formed on the main substrate 2001.

The main substrate 2001 may include a connector 2006 including a plurality of pins coupled with the external host. The number and arrangement of the plurality of pins in the connector 2006 may vary depending on a communication interface between the electronic system 2000 and the external host. In some example embodiments, the electronic system 2000 may communicate with the external host according to any one of interfaces such as a universal serial bus (USB), a peripheral component interconnect express (PCI-Express), a serial advanced technology attachment (SATA), an M-Phy for a universal flash storage (UFS), and the like. In some example embodiments, the electronic system 2000 may operate by power supplied from the external host through the connector 2006. The electronic system 2000 may further include a power management integrated circuit (PMIC) that distributes power supplied from the external host to the controller 2002 and the semiconductor package 2003.

The controller 2002 may record data in the semiconductor package 2003 or read data from the semiconductor package 2003, and may improve the operation speed of the electronic system 2000.

The DRAM 2004 may be a buffer memory to alleviate the speed difference between the semiconductor package 2003, which is a data storage space, and the external host. The DRAM 2004 included in the electronic system 2000 may also operate as a type of cache memory and provide a space to temporarily store data during control operations for the semiconductor package 2003. When the DRAM 2004 is included in the electronic system 2000, the controller 2002 may further include a DRAM controller for controlling the DRAM 2004 in addition to a NAND controller for controlling the semiconductor package 2003.

The semiconductor package 2003 may include a first semiconductor package 2003a and a second semiconductor package 2003b that are separated from each other. The first semiconductor package 2003a and the second semiconductor package 2003b each may be a semiconductor package including a plurality of semiconductor chips 2200. The first semiconductor package 2003a and the second semiconductor package 2003b each may include a package substrate 2100, a semiconductor chip 2200 on the package substrate 2100, an adhesive layer 2300 disposed on a bottom surface of each of the semiconductor chip 2200, a connection structure 2400 that electrically connects the semiconductor chip 2200 and the package substrate 2100, and a molding layer 2500 that covers the semiconductor chip 2200 and the connection structure 2400 on the package substrate 2100.

The package substrate 2100 may be a printed circuit board including a package upper pad 2130. Each semiconductor chip 2200 may include an input/output pad 2210. The input/output pad 2210 may correspond to the input/output pad 1101 of FIG. 26. Each semiconductor chip 2200 may include a gate stacking structure 4210 and a channel structure 4220. The semiconductor chip 2200 may include the semiconductor device described above with reference to the drawings.

In some example embodiments, the connection structure 2400 may be a bonding wire that electrically connects the input/output pad 2210 and the package upper pad 2130. Therefore, in each of the first semiconductor package 2003a and the second semiconductor package 2003b, the semiconductor chip 2200 may be electrically connected to each other using a bonding wire method and may be electrically connected to the package upper pad 2130 of the package substrate 2100. Depending on some example embodiments, in each of the first semiconductor package 2003a and the second semiconductor package 2003b, the semiconductor chips 2200 may be electrically connected to each other by a connection structure including a through silicon via (TSV) instead of the bonding wire type connection structure 2400.

In some example embodiments, the controller 2002 and the semiconductor chip 2200 may be included in one package. For example, the controller 2002 and the semiconductor chip 2200 are mounted on a separate interposer substrate different from the main substrate 2001, and the controller 2002 and the semiconductor chip 2200 may be connected to each other by a wire formed on the interposer substrate.

Referring to FIG. 28, in the semiconductor package 2003, the package substrate 2100 may be a printed circuit board. The package substrate 2100 may include a package substrate body portion 2120, the package upper pad 2130 disposed on an upper surface of the package substrate body portion 2120, a package lower pad 2125 that is disposed on a bottom surface of the package substrate body portion 2120 or exposed through the bottom surface, and an internal wire 2135 that electrically connects the package upper pad 2130 and the package lower pad 2125 in the package substrate body portion 2120. The package upper pad 2130 may be electrically connected with the connection structure 2400. The package lower pad 2125 may be connected to the wire pattern 2005 of the main substrate 2001 of the electronic system 2000 as shown in FIG. 27 through a conductive connection portion 2800.

Referring to FIG. 28, in a semiconductor package 2003a, each semiconductor chip 2200 may include a semiconductor substrate 4010, a first structure 4100 on the semiconductor substrate 4010, and a second structure 4200 bonded with the first structure 4100 using a wafer bonding method on the first structure 4100.

The first structure 4100 may include a peripheral circuit region including a peripheral wire 4110 and a first bonding structure 4150. The second structure 4200 may include a common source line 4205, a gate stacking structure 4210 between the common source line 4205 and the first structure 4100, a channel structure 4220 and a separation structure 4230 penetrating the gate stacking structure 4210, and a second bonding structure 4250 electrically connected with the channel structure 4220 and a word line of the gate stacking structure 4210. For example, the second bonding structure 4250 may be electrically connected to the channel structure 4220 and a word line WL through a gate connection wire that is electrically connected to a bit line 4240 and the word line WL, respectively.

As shown in FIG. 28, the second structure 4200 may include a 2-1 structure 4200a and a 2-2 structure 4200b that are bonded to each other. The 2-1 structure 4200a and the 2-2 structure 4200b may be bonded while being in contact with each other. A portion where the 2-1 structure 4200a and the 2-2 structure 4200b are bonded may be formed of, for example, copper (Cu).

The first bonding structure 4150 of the first structure 4100 and the second bonding structure 4250 of the second structure 4200 may be bonded while being in contact with each other. A bonding portion of the first bonding structure 4150 and the second bonding structure 4250 may be formed of, for example, copper (Cu).

In the semiconductor chip 2200 or semiconductor device according to some example embodiments, in the semiconductor device, one side of the channel structure CH is in contact with a bit line contact 183, which has a larger diameter than the channel structure CH. The bit line contact 183 may be formed in the same process when forming the channel structure CH, thereby limiting and/or preventing misalignment, and the separation pattern 170 may be formed by using the bit line contact 183 as a mask that covers the channel structure CH. Therefore, a part of the bit line contact 183 adjacent to the separation pattern 170 may be removed.

Each semiconductor chip 2200 may include an input/output pad 2210 and an input/output connection wire 4265 below the input/output pad 2210. The input/output connection wire 4265 may be electrically connected to some of the second bonding structure 4250.

In some example embodiments, a plurality of semiconductor chips 2200 in semiconductor package 2003 may be electrically connected to each other by a connection structure 2400 in the form of a bonding wire. As another example, a plurality of semiconductor chips 2200 or a plurality of portions forming the semiconductor chip 2200 may be electrically connected by a connection structure including a through silicon via.

One or more of the elements disclosed above may include or be implemented in processing circuitry such as hardware including logic circuits; a hardware/software combination such as a processor executing software; or a combination thereof. For example, the processing circuitry may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, an application-specific integrated circuit (ASIC), etc.

### DESCRIPTION OF SYMBOLS

130: gate electrode
160: separation structure
CH: channel structure
170: separation pattern
183: bit line contact
133: bit line insulation layer
134: channel insulation layer
181: bit line
182: contact via
184: auxiliary contact

What is claimed is:

1. A semiconductor device comprising:
a gate stacking structure including a plurality of interlayer insulation layers and a plurality of gate electrodes that are alternately stacked;
a separation structure penetrating the gate stacking structure;
a separation pattern separating some of the plurality of gate electrodes at a bottom side of the gate stacking structure;
a channel structure penetrating the gate stacking structure;
a channel insulation layer on the gate stacking structure, the channel insulating layer defining a plurality of grooves therein;
a bit line contact in a groove from among the plurality of grooves, the bit line contact being electrically connected with the channel structure and being in contact with the separation pattern;
a bit line insulation layer on the bit line contact; and
a bit line on the bit line insulation layer, the bit line being electrically connected with the bit line contact,
wherein a planar area of the bit line contact is larger than a planar area of the channel structure that is in contact with the bit line contact,
a planar shape of a portion of the bit line contact in contact with the separation pattern is different than a planar shape of another portion of the bit line contact that is not in contact with the separation pattern, and
the separation pattern and the bit line insulation layer are integrally connected through the groove penetrating the channel insulation layer.

2. The semiconductor device of claim 1, wherein
the planar shape of the portion of bit line contact in contact with the separation pattern has a non-circular shape and the planar shape of the another portion of the bit line contact that is not in contact with the separation pattern has a circular shape.

3. The semiconductor device of claim 1, wherein
a diameter of the channel structure away from the bit line contact is larger than a diameter of the channel structure adjacent to the bit line contact.

4. The semiconductor device of claim 1, wherein
a diameter of the separation structure away from the bit line contact is larger than a diameter of the separation structure adjacent to the bit line contact.

5. The semiconductor device of claim 1, further comprising a contact via between the bit line contact and the bit line,
wherein the bit line contact and the bit line are connected by the contact via.

6. The semiconductor device of claim 5, further comprising an auxiliary contact between the bit line contact and the contact via,
wherein a diameter of the auxiliary contact is larger than a diameter of the contact via.

7. The semiconductor device of claim 1, wherein
the channel structure comprises a gate dielectric layer, a channel layer, and a first semiconductor pattern and a second semiconductor pattern respectively at first and second ends of the channel structure.

8. The semiconductor device of claim 7, wherein
the bit line contact is in contact with the first semiconductor pattern of the channel structure.

9. The semiconductor device of claim 7, further comprising a common source electrode on a side of the gate stacking structure opposite the bottom side of the gate stacking structure,
wherein the second semiconductor pattern of the channel structure and the common source electrode are in contact with each other.

10. The semiconductor device of claim 1, further comprising another bit line contact in another groove from among the plurality of grooves,
wherein the separation structure comprises a first layer, a second layer, a third layer, and a first semiconductor pattern and a second semiconductor pattern respectively at first and second ends of the separation structure, and
the another bit line contact is in contact with the first semiconductor pattern of the separation structure.

11. The semiconductor device of claim 1, wherein
a side of the bit line contact away from the gate stacking structure does not contact the channel insulation layer, and
another side of the bit line contact adjacent to the gate stacking structure contacts the channel insulation layer.

12. The semiconductor device of claim 1, wherein
a planar area of the separation pattern outside the gate stacking structure is larger than a planar area of the separation pattern penetrating the gate stacking structure.

13. A semiconductor device comprising:
a gate stacking structure including a plurality of interlayer insulation layers and a plurality of gate electrodes that are alternately stacked;
a separation structure penetrating the gate stacking structure along a first direction, the separation structure extending in a second direction;
a separation pattern separating some of the plurality of gate electrodes at a bottom side of the gate stacking structure, the separation pattern penetrating the gate stacking structure along the first direction and extending in the second direction;
a channel structure between the separation structure and the separation pattern on a plane, the channel structure penetrating the gate stacking structure along the first direction;
a channel insulation layer on the gate stacking structure, the channel insulating layer defining a plurality of grooves therein;
a bit line contact in a groove from among the plurality of grooves, the bit line contact being electrically connected with the channel structure and being in contact with the separation pattern;
a bit line insulation layer on the bit line contact;
a bit line on the bit line insulation layer, the bit line extending in a third direction that is perpendicular to the second direction, and the bit line being electrically connected with the bit line contact; and
a contact via between the bit line contact and the bit line,
wherein the separation pattern and the bit line insulation layer are integrally connected through the groove penetrating the channel insulation layer,
a planar area of the bit line contact is larger than a planar area of the channel structure that is in contact with the bit line contact, and
a planar shape of the bit line contact has a circular shape in some regions and has a non-circular shape in other regions.

14. The semiconductor device of claim 13, wherein
a planar area of a portion the bit line contact in contact with the separation pattern is smaller than a planar area of another portion of the bit line contact that is not in contact with the separation pattern.

15. The semiconductor device of claim 13, further comprising an auxiliary contact between the bit line contact and the contact via,
wherein a diameter of the auxiliary contact is larger than a diameter of the contact via.

16. The semiconductor device of claim 13, wherein
the channel structure comprises a gate dielectric layer, a channel layer, and a first semiconductor pattern and a second semiconductor pattern respectively at first and second ends of the channel structure, and
the first semiconductor pattern of the channel structure contacts the bit line contact.

17. The semiconductor device of claim 13, wherein
a side of the bit line contact away from the gate stacking structure does not contact the channel insulation layer, and
another side of the bit line contact adjacent to the gate stacking structure contacts the channel insulation layer.

18. An electronic system comprising:
a main substrate;
a semiconductor device on the main substrate; and
a controller electrically connected with the semiconductor device on the main substrate,
wherein the semiconductor device comprises
a gate stacking structure including a plurality of interlayer insulation layers and a plurality of gate electrodes that are alternately stacked,
a separation structure penetrating the gate stacking structure,
a separation pattern separating some of the plurality of gate electrodes at a bottom side of the gate stacking structure,
a channel structure penetrating the gate stacking structure,
a channel insulation layer on the gate stacking structure, the channel insulation layer defining a plurality of grooves therein,
a bit line contact in a groove from among the plurality of grooves, the bit line contact being electrically connected with the channel structure and being in contact with the separation pattern,
a bit line insulation layer on the bit line contact, and
a bit line on the bit line insulation layer, the bit line being electrically connected with the bit line contact,
wherein a planar area of the bit line contact is larger than a planar area of the channel structure that is in contact with the bit line contact,
a planar shape of a portion of the bit line contact in contact with the separation pattern is different than a planar shape of another portion of the bit line contact that is not in contact with the separation pattern, and
the separation pattern and the bit line insulation layer are integrally connected through the groove penetrating the channel insulation layer.

19. The electronic system of claim 18, wherein
a diameter of the channel structure away from the bit line contact is larger than a diameter of the channel structure adjacent to the bit line contact, and
a diameter of the separation structure away from the bit line contact is larger than a diameter of the separation structure adjacent to the bit line contact.

20. The electronic system of claim 18, wherein
the channel structure comprises a gate dielectric layer, a channel layer, and a first semiconductor pattern and a second semiconductor pattern respectively at first and second ends of the channel structure, and
the bit line contact is in contact with the first semiconductor pattern of the channel structure.
